(19) United States
(12) Patent Application Publication
(10) Pub. No.: US 2026/0197966 A1
(43) Pub. Date: Jul. 9, 2026

(54) TANK FOR COOLING OF COMPUTING DEVICES USING LIQUID IMMERSION

(71) Applicant: FIRMUS METAL TECHNOLOGIES SINGAPORE PTE LTD, Singapore (SG)

(72) Inventors: Hamish KERR, Cremorne (AU); Andrew BULS, Cremorne (AU); Oliver CURTIS, Cremorne (AU); Jonathan LEVEE, Cremorne (AU)

(21) Appl. No.: 19/128,706

(22) PCT Filed: Nov. 10, 2023
(86) PCT No.: PCT/AU2023/051137

§ 371 Date: May 9, 2025

(30) Foreign Application Priority Data
Nov. 10, 2022 (AU) 2022903367
Nov. 10, 2022 (AU) 2022903371
Nov. 10, 2022 (AU) 2022903375

(51) Int. Cl. H05K 7/20; H05K 7/14

(52) U.S. Cl. CPC H05K 7/20236; H05K 7/1489; H05K 7/20763

(57) ABSTRACT

A cooling tank for cooling computing devices using liquid immersion is disclosed. The cooling tank comprises: a container configured to receive coolant in a cavity of the container; a separation panel dividing the container cavity into a cooling space and a return space; a perforated panel connected to the container and the separation panel to partition an inlet space from the cooling space; a racking system configured to support the computing devices within the cooling space; a coolant inlet conduit configured to release the coolant into the inlet space; a coolant outlet conduit disposed within the return space; wherein perforations defined in the perforated panel allow passage of the coolant from the inlet space into the cooling space to cool the computing devices therein; and wherein a top portion of the separation panel is disposed further from the bottom panel compared to an inlet of the coolant outlet conduit.

### TECHNICAL FIELD

Described embodiments relate to systems for cooling computing devices. In some embodiments, the systems relate to cooling tanks for use in cooling computing devices.

### BACKGROUND

A data centre usually hosts hundreds, thousands, or tens of thousands of computing devices or servers to perform computing tasks. These computing devices generate a significant amount of heat during operation. The heat generated from the computing devices must be dissipated for the computing devices to operate properly. Otherwise, the computing devices may be damaged due to the accumulated heat in the data centre. Therefore, a cooling system is required to be installed in the data centre to dissipate the heat. Both the computing devices and the cooling system in the data centre consume electricity. Power Usage Effectiveness (PUE) is used to measure the effectiveness of power usage, which is defined as a ratio of total power consumed by a data centre to the power delivered to the computing devices or severs performing the computing tasks. For example, a data centre consumes a total power of 10,000 KW, which is used to power the servers and other equipment, primarily, the cooling system to cool the servers. At the same time, 8,000 KW out of the total power is used to power the servers. Therefore, the PUE of the data centre is 10,000 KW/8,000 KW=1.25. Usually, a lower PUE means less wastage of electricity, lower operating costs, and more competitive advantages. There are environmental and commercial benefits for providing a data centre with low PUE.

It is desired to address or ameliorate some of the disadvantages associated with such prior methods and systems, or at least to provide a useful alternative thereto.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each of the appended claims.

### SUMMARY

In some embodiments, a cooling tank for cooling computing devices comprises: a plurality of first racking members, configured to engage with at least one side wall of a container; a plurality of second racking members configured to engage with the plurality of first racking members; a plurality of third racking members configured to engage with the plurality of second racking members. The plurality of third racking members may be adapted to receive one or more computing devices, such that when the one or more computing devices are received by the plurality of third racking members, the one or more computing devices are mounted within the container. When the plurality of first racking members engage with at least one side wall of the container, and each of the plurality of second racking members engages with at least two of the plurality of first racking members, the plurality of first racking members and the plurality of second racking members may form a support structure within the container, such that the support structure resists deflection of at least one side wall of the container when the container contains liquid coolant.

The container may further comprise a separation panel disposed proximal to a first side wall of the container, the separation panel defining a plurality of fenestrations and defining a return zone between the first side wall and the separation panel.

Each of the plurality of first racking members may comprise one or more first mating structures and each of the plurality of second racking members may comprise one or more second mating structures, the one or more second mating structures configured to interact with the one or more first mating structures.

The one or more first mating structures and the one or more second mating structures may be configured to interact through the plurality of fenestrations defined by the separation panel.

A first edge of the plurality of third racking members may be substantially parallel to a bottom panel of the container. Each of the one or more computing devices may comprise at least two support brackets, configured to abut against the first edge of the plurality of third racking members. When the at least two support brackets of each of the one or more computing devices abuts against the first edge of the plurality of third racking members, the one or more computing devices may be caused to hang substantially perpendicular to the bottom panel.

Each of the plurality of third racking members may define a guide portion, configured to abut against one or more computing devices when one or more computing devices are mounted in the rack.

The computer device mounting rack may be compatible with one or more of a standard rack unit rack member, a standard rack unit computing device and/or ASIC computing device.

One or more of the plurality of first racking members, the plurality of second racking members and/or the plurality of third racking members may comprise one or more cable support structures.

The plurality of second racking members and/or the plurality of third racking members may be further configured to route one or more cables configured to engage with the one or more computing devices.

In some embodiments, a cooling tank for cooling computing devices may comprise: a container, comprising at least four side walls, the side walls defining at least four container edges wherein the container edges are substantially perpendicular to a container base and comprise at least one mounting brackets, each of the at least one mounting brackets comprising at least one first mounting structure; a plurality of supporting structures, each supporting structure comprising a set of reinforcing members in contact with the at least four side walls, wherein each of the plurality of supporting structures is configured to extend substantially around an outer perimeter of the container defined by the side walls parallel to the container base. Each reinforcing member may comprise at least one second mating structure configured to interface with the at least one first mounting structures. The reinforcing members may substantially resist deflection of the container walls when the container contains liquid coolant.

The tank may comprise three supporting structures. Each supporting structure may comprise four reinforcing members.

The coolant tank may comprise a separation panel disposed in an internal space of the container. The separation panel may be configured to alter the flow characteristics of the liquid coolant.

The coolant tank may comprise a set of first coolant conduits, a set of second coolant conduits and a set of balance conduits configured to convey liquid coolant in and/or out of the container.

One of the at least four container walls may be a first container wall. The set of first coolant conduits, the set of second coolant conduits and the set of balance conduits may extend between the first container wall and the separation panel.

The set of first coolant conduits, the set of second coolant conduits and the set of balance conduits may be configured to convey liquid coolant into and/or out of the container.

The set of balance conduits may be further configured to isolate the tank from one or more connected tanks and/or conduits.

The coolant tank may further comprise at least one set of overflow conduits. The overflow conduits may be in fluidic connection with one or more neighbouring tanks.

At least some of the reinforcing members forming at least one of the supporting structures may have a thickness in the range 1.6 mm to 3 mm.

At least some of the reinforcing members forming at least one of the supporting structures may have a width in the range 50 mm to 100 mm.

The supporting structures may be positioned so as to be evenly spaced from each other across at least one of the side walls.

The tank may have an operational volume of between 1200 litres and 1400 litres of liquid coolant.

The tank may further comprise insulation disposed on one or more of the outer faces of the at least four side walls.

The tank may further comprise at least one exterior cladding panel.

The tank may further comprise a plurality of cable routing members.

The coolant tank may further comprise a covering, disposed on the opening of the container, distal from the bottom panel. The covering may comprise a body portion. The body portion may comprise: a securing portion, for securing the body portion to the container; one or more cable fenestrations; and one or more closure control mechanisms; a lid portion, hingedly connected to the body portion, the lid portion comprising one or more viewing windows. The one or more closure control mechanisms may be configured to resist movement of the lid portion from an open position to a closed position.

The cooling tank may further comprise one or more computing devices and a volume of liquid coolant.

In some embodiments, a system for cooling computing devices may comprise: a plurality of cooling tanks as described herein; a heat exchanger; a heat dissipater; at least one liquid coolant pump; a volume of liquid coolant; a plurality of inlet conduits configured to convey the volume of liquid coolant from the at least one liquid coolant pump to the plurality of cooling tanks; a plurality of outlet conduits configured to convey the volume of liquid coolant from the plurality of cooling tanks to the heat exchanger.

Some embodiments relate to a cooling tank for cooling computing devices, the cooling tank comprising:
a container configured to receive coolant in a cavity of the container, the container comprising a bottom panel and a plurality of side walls extending from the bottom panel, wherein two of the side walls are oppositely disposed;
a separation panel disposed within the container, the separation panel connected to: (i) the oppositely disposed side walls; and (ii) the bottom panel; to divide the container cavity into a cooling space and a return space;
a perforated panel disposed towards the bottom panel of the container and connected to: (i) the oppositely disposed side walls; and (ii) the separation panel; to partition an inlet space from the cooling space;
a racking system configured to support the computing devices within the cooling space;
a coolant inlet conduit configured to release the coolant into the inlet space;
a coolant outlet conduit disposed within the return space and extending out of the container;
wherein perforations defined in the perforated panel are configured to allow passage of the coolant from the inlet space into the cooling space to cool the computing devices therein; and
wherein a top portion of the separation panel is disposed further from the bottom panel compared to an inlet of the coolant outlet conduit.

An inlet of the coolant outlet conduit may be configured to receive a plug. The plug may define a second inlet to the coolant outlet conduit, wherein the second inlet is configured to be disposed further from the bottom panel compared to a top portion of the separation panel. The racking system may comprise a cover plate configured to receive a top portion of one of the computing devices, wherein the top portion is below the top portion of the separation panel.

The racking system may be connected to one or both of: (ii) the separation panel; and (ii) at least one of the plurality of side walls; to provide structural reinforcement of the container. The coolant inlet conduit may be disposed within the return space and extends into the inlet space through apertures in the separation panel.

### BRIEF DESCRIPTION OF DRAWINGS

FIG. 1 is a schematic diagram of a cooling system for cooling computing devices, according to some embodiments;

FIG. 2A is a schematic drawing of a cooling system for cooling computing devices, according to some embodiments;

FIGS. 2B and 2C are schematic drawings of the cooling system of FIG. 2A connected to a drain and fill system, according to some embodiments;

FIGS. 3A, 3B, 3C, 3C (inset), and 3D are schematic drawings of a cooling tank, according to some embodiments, wherein FIG. 3C (inset) is a simplified schematic of FIG. 3C;

FIG. 4 is an image of a mounting arrangement, for a cooling tank, according to some embodiments;

FIG. 5 is an image of an exterior cladding panel for a cooling tank, according to some embodiments;

FIGS. 6A, 6B, 6C and 6D are images of a covering for a cooling tank, according to some embodiments;

FIGS. 7A, 7B, 7C, 7D, 7E, 7F and 7G are schematic diagrams of a rack system for a cooling tank, according to some embodiments;

FIG. 8 is an image of a cable management system of a rack system for a cooling tank, according to some embodiments; and

FIG. 9 is a diagram showing a plug for the coolant conduits and the balance conduits, according to some embodiments.

### DETAILED DESCRIPTION OF EMBODIMENTS

Large conglomerates of computing devices are used to perform such operations as hosting websites, storing data, and/or engaging in computationally complex operations such as solving proof of work equations, rendering complex images and/or running large neural networks. Large numbers of computing devices operating at elevated processing speeds in close proximity generate non-negligible amounts of excess heat energy. To maintain optimal performance, these computing devices must have their excess heat energy absorbed and moved away or otherwise dissipated lest the computing devices thermal throttle, leading to a reducing in processing speed, resulting in lost performance and potential failure.

Groups of computing devices may be cooled by having air moved across heat generating components, such as central processing units (CPUs), graphical processing units (GPUs), random access memory (RAM) and/or motherboard chipsets. Computing devices may also have their components cooled using a cooling liquid, such as water, routed from one heat generating component to another to form a water loop, usually attached to a reservoir and a pumping mechanism. Large numbers of computing devices may be cooled by immersion cooling, which involves immersing the computing devices in a non-conductive liquid, such as a synthetic hydrocarbon oil. The computing devices may be submerged in this non-conductive liquid, allowing the liquid to permeate through the chassis of the computing devices, running over the heat generating components, absorbing said heat and moving it away.

Immersion cooling may allow for computing devices to be placed more proximal to one another when compared to other methods of cooling, as the liquid may be a more effective heat sink, and may be allowed to fully contact all parts of a computing device and passively absorb heat, instead of needing to be mechanically moved across a surface such as with conventional water loops or air cooling.

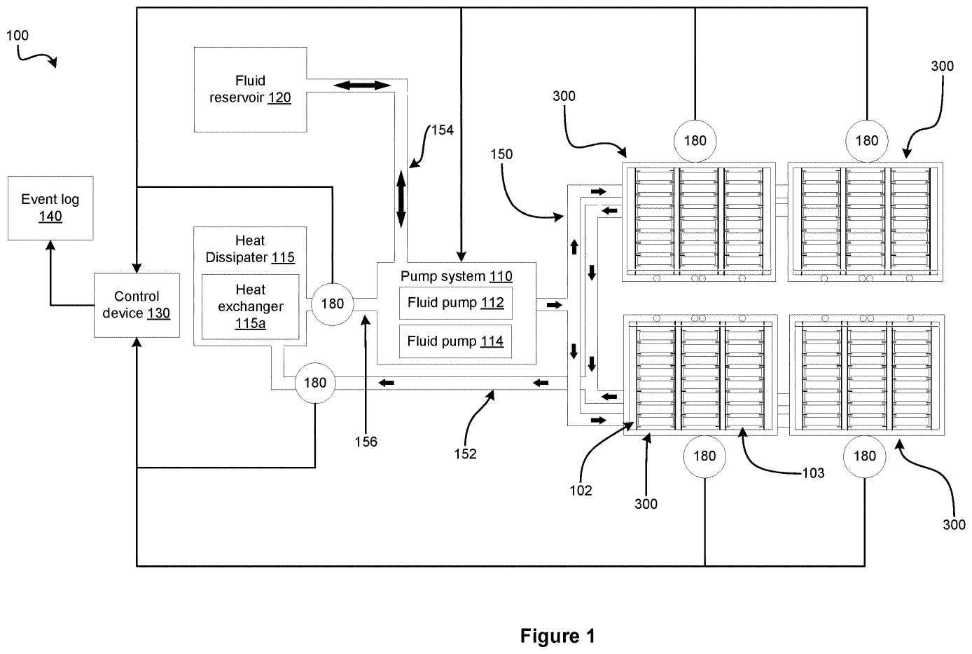

FIG. 1 is a block diagram of a cooling system 100, according to some embodiments. System 100 may comprise one or more tanks 300. System 100 may also comprise one or more pump systems 110. System 100 may also comprise one or more heat dissipaters 115. System 100 may also comprise one or more fluid reservoirs 120. System 100 may also comprise one or more control device 130. The system 100 may also comprise one or more event log 140. The system 100 may be used to cool computing devices 103 during operation.

The system 100 may be configured to provide immersion cooling of the computing devices 103. Accordingly, the system 100 may be accommodated in a smaller footprint compared to conglomerates of computing systems generating the same amount of heat energy, and/or having comparable combined processing capabilities. Allowing for a smaller footprint may provide for a more easily implemented modular system, that may be scaled up or down quickly, easily and in a modular fashion.

The system 100 may comprise a plurality of conduits connecting components of the system 100. The conduits may be configured to direct a cooling fluid (such as a non-conductive liquid) between the components of the system 100 to facilitate cooling of the computing devices 103. The various conduits of the system 100 may be formed from tubes, pipes and/or a combination of tubes and pipes. Pipes may be hollow conduits with round cross sections, and tend to be rated for higher internal pressures and have a rougher internal surface compared to tube. The tubes may be hollow conduits with a round, square, rectangular and/or oval cross section, and are generally rated to lower internal pressures than pipe, but have a smoother internal surface. Accordingly, tube may be better suited to facilitating uniform flow regimes within the system 100, and may be better for low pressure systems and systems where space and conduit configuration play a key role.

The system 100 may also be adapted and/or configured to facilitate substantially similar or identical conditions of the system coolant throughout most or all parts of system 100 at substantially all times during operation. Similar or identical conditions may be the same volume of system coolant in any point of the system 100 as in any comparable point in the system 100, for example the same volume of liquid in one inlet conduit 150 and another different inlet conduit 150. Similar or identical conditions may be the pressure, pressure differential and/or maximum velocity pressure at any point in the system 100 as in any comparable point of the system 100. When system 100 is operating within normal operational conditions, the system coolant throughout the system 100 may be consider to be in equilibrium. Similar or identical conditions may also be the same volume of system coolant passing through any point in the system 100 as through any comparable point of the system 100. The present disclosures may achieve this by maintaining a uniform flow regime through the conduits of the system 100.

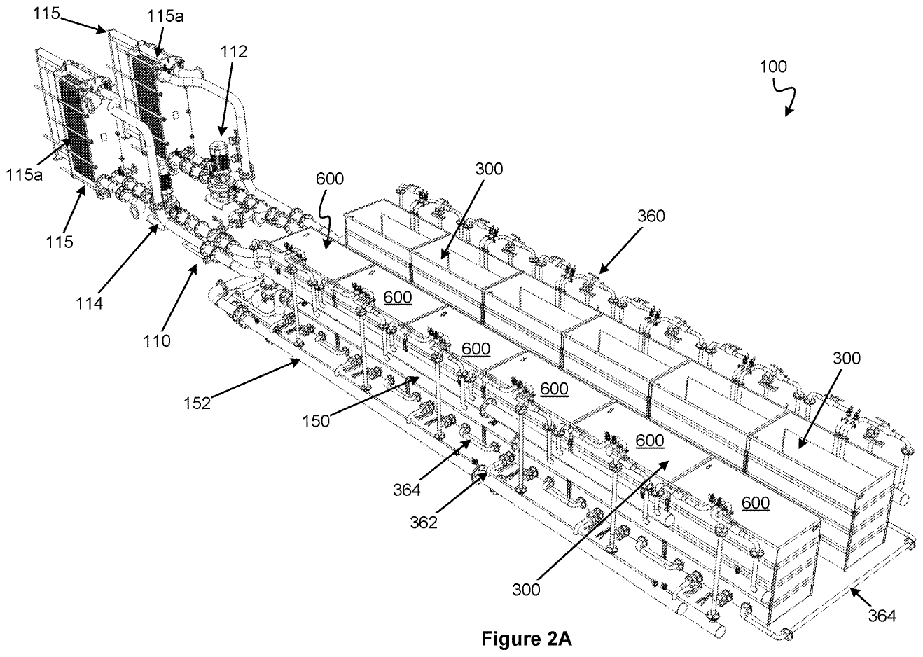

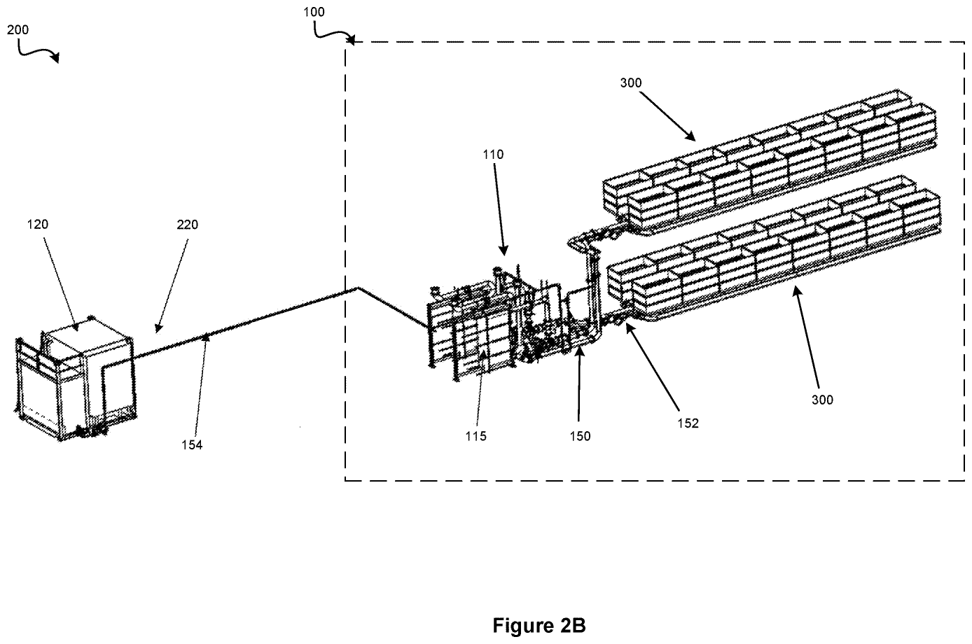

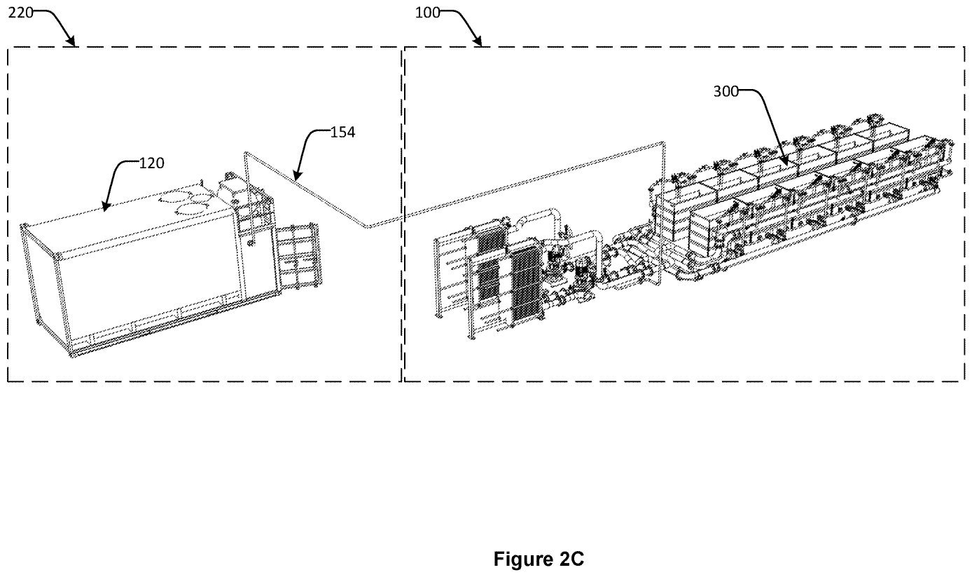

The tanks 300 may be in fluidic connection with other tanks 300, pump system 110, heat dissipater 115, and/or fluid reservoir 120 by one or more fluid conduits. Tanks 300 may comprise one or more computing device racks 102 which may comprise one or more computing devices 103. Tanks 300 may be configured into racks and/or rows of tanks that share common coolant conduits (as shown in FIG. 2A) that connect each tank to each other and to the rest of system 100. Neighbouring tanks 300 may also be fluidically connected to each other by one or more balance conduits and/or one or more overflow conduits.

The pump system 110 may be in fluidic communication with heat dissipater 115, fluid reservoir 120, and/or one or more tanks 300 by one or more coolant conduits. Pump system 110 may be configured to pump system coolant throughout the system 100 to collect excess heat energy from computing devices 103 in tanks 300 and dissipate it at heat dissipater 115.

In some embodiments, pump system 110 may comprise one or more fluid pumps 112, 114. Pump system 110 may comprise multiple fluid pumps depending on the volume of system coolant contained in system 100, and/or the number of tanks 300 in system 100. In some embodiments, fluid pump 112 may be a primary or first coolant pump and fluid pump 114 may be a secondary, back-up or second coolant pump. Fluid pump 114 may be kept at an idle rate and/or power usage, such as 50% of its full power, and be caused to ramp up to a higher rate and/or power usage upon a trigger event. A trigger event may comprise a power spike, a malfunction event, a reduction in system coolant velocity, an increase in system coolant velocity and/or any other trigger that may represent anomalous and/or non-stand behaviour of the system 100. In some embodiments, fluid pumps 112, 114 may both be operating at 50% of their full power and both be causing the system coolant to be conveyed throughout the system and upon a trigger event, one of the fluid pumps 112, 114 may be caused to ramp down to a lower output, and the other one of the fluid pumps 112, 114 may be caused to ramp up its output to accommodate. The pumps may also be in any other configuration of reduced or increased power output relative to one another, such as 10-90, 20-80, 30-70, 40-60, for example. However, a 0-100 or 50-50 configuration may be preferred in some cases, as this assist in facilitating the substantially even distribution of system coolant throughout the system.

The heat dissipater 115 may be in fluidic connection with fluid pump 110, fluid reservoir 120, and/or tanks 300 by one or more coolant conduits. Heat dissipater 115 may be configured to receive the system coolant, or another secondary coolant fluid, such as water, that has absorbed excess heat generated by the computing devices 103 and dissipate it to the surrounding environment and/or atmosphere. In some embodiments, heat dissipater 115 may be an adiabatic cooling system, configured to receive the system coolant, or one or more secondary coolant fluids, such as air or water.

In some embodiments, heat dissipater 115 may comprise one or more heat exchangers 115a. The heat exchanger may be an oil to water interface, wherein the system coolant (i.e. oil) flowing between the tanks 300, and may transfer collected heat energy to a volume of water. Heat dissipater may exchange heat from the oil by bringing an oil conduit into close proximity with a water conduit, to allow the heat energy within the oil to radiate to the water.

In some embodiments, the heat dissipater 115 may also comprise, either alone or in combination with other described elements one or more of a water tower, natural water source, and/or geothermal conduit system, for example, which may be configured to transfer heat from the system 100 into the surrounding environment to cool the system coolant back down, before being fed back into the system 100.

Fluid reservoir 120 may be in fluidic connection with tanks 300, fluid pump 110, and/or heat dissipater 115 by one or more coolant conduits. Fluid reservoir 120 may be configured to collect and/or store some or all of the volume of oil within the system 100. Oil within the system 100 may be caused to be conveyed to the fluid reservoir 120 by fluid pump 110 and/or one or more reservoir pumps (not shown) when the system 100 or components of system 100 such as fluid pump 110, tanks 300, racks 102, computing devices 103, and/or heat dissipater 115 require maintenance, replacement and/or reconfiguration. Fluid reservoir 120 may be mechanically isolated from the rest of system 100 until oil is required to be moved to and stored in fluid reservoir 120. In some embodiments, fluid reservoir 120 may be a moveable container that may be connected or removed from the system 100 as needed.

Control device 130 may be one or more computing devices 103 in communication with one or more, electrical control systems (not shown), and/or one or more temperature probes 180, to monitor temperatures and/or flow characteristics throughout the system 100. Temperature probes 180 may be installed in outlet conduit 152, return conduit 156, inside tanks 300 and/or at the inlets and/or outlets of tanks 300. In some embodiments, temperature probes 180 may be positioned proximal to the inlet and/or the outlet of heat dissipater 115. Control device 130 may also be in communication with event log 140, to send operational notifications. In some embodiments, when the control device detects conditions in system 100 that are outside of normal operating parameters, such as via one or more temperature probes 180, control device 130 may be configured to communicate a notification to event log 140. The notification may be stored in an ordered list at event log 140, tracking the performance of system 100. In some embodiments, control device 130 may also be configured to periodically, aperiodically and/or manually perform a system check to determine if system 100 is operating properly. Control device 130 may also continuously monitor the conditions of system 100 and provide a continuous stream of information to event log 140.

Control device 130 may also be configured to monitor the temperature of the system coolant and/or the performance of system 100. Control device 130 may be configured to read one or more temperatures of the system coolant at one or more points in system 100, and adjust the operation of one or more components of the system accordingly. For example, control device 130 may adjust the operation of one or more pipes or valves to increase or decrease a flowrate of a fluid through heat dissipater 115. The control device 130 may read the temperature of the system coolant using one or more temperature probes situated throughout the system 100, such as at the intake and/or outlet of the heat dissipater 115.

As shown in FIG. 1, pump system 110 may be fluidically connected to tanks 300 by coolant inlet conduit 150, such that system coolant may be pumped or otherwise supplied to tanks 300. Tanks 300 may be fluidically connected to heat dissipater 115 via coolant outlet conduit 152. Heat dissipater 115 may be fluidically connected with pump system 110 by coolant return conduit 156. In some embodiments, pump system 110 may also be in fluidic connection with fluid reservoir 120 by drain and fill pipes 154.

FIG. 2A is a schematic diagram of a cooling system 100 for cooling computing devices 103. To allow the other features of system 100 to be shown clearly, the computing devices 103 are not shown in FIG. 2A. The computing devices 103 will be understood to be contained in the tanks 300, unless otherwise stated. The cooling system 100 can be used to cool computing devices 103, which may be operating in a data centre. The cooling system 100 comprises the cooling tank(s) 300. As shown in FIG. 2A, the exemplary cooling system 100 includes 12 cooling tanks 300 arranged in two rows, positioned substantially parallel to each other. The cooling tanks 300 may be mounted or otherwise placed on a scaffold or mounting rack (not shown). In some embodiments, the system 100 may comprise more than 12 tanks 300 or fewer than 12 tanks 300. The tanks 300 may be arranged on a in single rows (i.e. without another adjacent row as depicted in FIG. 2A), in multiple rows spaced across multiple levels (i.e. one or more upper and lower rows), and/or vertical stacks. For example, the cooling system 100 may include 16 cooling tanks 300 over two decks with 8 cooling tanks 300 on each deck. In FIG. 2A, one row of the tanks 300 is shown with a covering 600, while the other row of the tanks 300 is shown uncovered to allow the inside of the tanks 300 to be seen.

The description below in relation to the elements installed on one or more lower decks also applies to the elements installed on one or more upper decks or other deck(s) if any. The description below in relation to a row of cooling tanks 300 on a deck also applies to another row of cooling tanks on the same deck. As another example, a cooling system 100 as described with reference to FIG. 2A may be used as a sub cooling system, and another cooling system 100 may be used as another sub cooling system. The two sub cooling systems 100 can be fluidly connected together to form a cooling system. Such a cooling system including more than one sub cooling systems 100 is also described in the present disclosure. A pipe in the present disclosure can be a straight pipe, a bent pipe, a curved pipe, or a combination of pipes in different shapes. A pipe can also include one or more segments that are fluidly connected. Further, a tube in the present disclosure may be a straight tube, a bent tube, a curved tube, or a combination of tubes in different shapes and/or configurations. The one or more segments of a pipe can extend towards the same direction or different directions. Further, the reference to the segments of a pipe is not to define the structure of the pipe, but to indicate different portions of the pipe for easy description. In some embodiments, conduit sections may be joined by a flange connection.

For ease of description, the multiple cooling tanks 300 are individually denoted as 300. Any cooling tank 300 may have the same structure and work in the same way as any other the cooling tanks 300 in the present system. Each of the cooling tanks 300 is configured to accommodate a system coolant and sized to immerse at least a portion of the computing devices 103 (not shown in FIG. 2A) in the system coolant so the system coolant can absorb heat generated from the computing devices 103 so as to cool the computing devices 103. During operation of the cooling system 100 and the data centre, one or more computing devices 103 are placed in each of the cooling tanks 300, and the heat generated from the computing devices 103 is absorbed by the system coolant in the cooling tanks 300 to reduce the temperature of the computing devices 103. As a result, the system coolant around the computing devices 103 heats up and its temperature becomes higher. The system coolant can be for example a cooling oil.

The system coolant of the present disclosures may be a type of dielectric fluid. A dielectric fluid is a non-conductive fluid that has a very high resistance to electrical breakdown event at high voltages. Electrical breakdown or dielectric breakdown is when an insulating (i.e. non-conductive) material becomes an electrical conductor. The present system may use such dielectric fluids as oils, for example synthetic oil, mineral oil or bioorganic oil, or an engineered fluid, such as 3M's Novec or Fluorinert lines. In some embodiments, the system 100 may use a synthetic hydrocarbon oil, as synthetic hydrocarbon oils repel water and other foreign bodies.

The cooling system 100 also comprises one or more pairs of coolant conduits. In some embodiments, each pair of coolant conduits comprises an inlet conduit 150 and an outlet conduit 152. The inlet conduit 150 of each set of coolant conduits may be fluidly connected to each of the cooling tanks 300 in a row, to supply the system coolant into the multiple cooling tanks 300. The system coolant may be supplied into the cooling tanks 300 in a row from the bottoms of the cooling tanks 300 via the inlet conduit 150 of each of the pair of coolant conduits.

The outlet conduit 152 of each set of coolant conduits is fluidly connected to the multiple cooling tanks 300 in a row, to convey the system coolant carrying the heat absorbed from the computing devices 103 out of the multiple cooling tanks 300 in the row. The system coolant carrying the heat is conveyed out of the cooling tanks 300 via the outlet conduit 152 of each pair of coolant conduits.

The cooling system 100 also comprises a heat dissipater 115. The heat dissipater 115 fluidly connects to each inlet conduit 150 of each pair of coolant conduits, directly or indirectly to supply the system coolant into the set of inlet conduits 150. The heat dissipater 115 also fluidly connects to each of the outlet conduits 152 of each of the pairs of coolant conduits, directly or indirectly to receive from the outlet conduits 152 of each of the pairs of coolant conduits, the system coolant carrying the heat absorbed from the computing devices 103. The heat dissipater 115 is configured to dissipate the heat from the system coolant carrying the heat. Therefore, the temperature of the system coolant is reduced and the system coolant is supplied into the inlet conduits 150 of each of the pairs of coolant conduits, and in turn the multiple cooling tanks 300 of each row, to cool the computing devices 103 immersed in the system coolant in the multiple cooling tanks 300 of each row.

The cooling system 100 also comprises a pump system 110 that fluidly connects to each of the inlet conduits 150 and outlet conduits 152 of each pair of coolant conduits, directly or indirectly. The pump system 110 is configured to facilitate circulation of the system coolant in the multiple cooling tanks 300, the inlet conduits 150, the outlet conduits 152, and the heat dissipater 115. Cooling systems configured as described in some embodiments may allow for a large quantity of cooling tanks 300 to be connected to a single coolant distribution system, which may have just a single pump system 110 and single heat dissipater 115 in some embodiments. A single pump system 110 and single heat dissipater 115 reduces complexity compared to a system with several pumps and heat dissipaters. This may reduce power consumption. This may allow for easier and cheaper operation and maintenance.

In the cooling system 100, the heat dissipater 115 fluidly connects to the multiple cooling tanks 300 of a row via the inlet conduits 150 and the outlet conduits 152 of each pair of coolant conduits. Further, the pump system 110 fluidly connects to the multiple cooling tanks 300 of a row via the outlet conduit 152 of each pair of coolant conduits. Such a structure makes it unnecessary for the multiple cooling tanks 300 to have their individual heat dissipaters and their individual coolant pumps to dissipate the heat and circulate the system coolant because the heat dissipater 115 and the pump system 110 are shared by the multiple cooling tanks 300. Therefore, the cooling system 100 allows a scalable deployment of the data centre, i.e. additional rows of cooling tanks 300 may be added into the cooling system 100 simply by fluidically attaching their particular inlet and outlet conduits to the system 100.

The cooling system 100 may also comprise a water supply pipe (not shown) fluidly connected to the heat dissipater 115 to supply water (for example, cool water) into the heat dissipater 115 in order for the heat dissipater 115 to dissipate the heat into the water. The cooling system 100 also comprises a water release pipe (not shown) fluidly connected to the heat dissipater 115 to release from the heat dissipater 115 the water with the heat (i.e., hot water).

In some embodiments, the cooling system 100 may comprise a drain and fill system 220, such as shown in FIG. 2B and FIG. 2C. Drain and fill system 220 may comprise coolant reservoir 120 and the drain and fill pipes 154 and may be used, for example, when the one or more cooling tanks 300 need to be drained for operational requirements and serviceability. The drain and fill system 220 may further comprise one or more drain and fill pumps (not shown), for conveying fluid into or out of coolant reservoir 120 via drain and fill conduit 154. The use of multiple tanks 300 connected to one heat dissipater 115 (or heat exchanger 115a) and pump system 110 may allow for fewer moving parts. This may create efficiencies in operation. This may allow for easier and cheaper operation and maintenance.

The drain and fill system 220 is configured to drain the system coolant from one or more cooling tanks 300. The drain and fill system 220 is configured to direct the system coolant into one or more cooling tanks 300 to fill the tank 300 with coolant. This way, if the one or more cooling tanks 300 need to be serviced, the drain and fill system 220 drains the system coolant from one or more cooling tanks 300. After the service is finished, the drain and fill system fills the system coolant into the one or more cooling tanks 300. In some embodiments, system 100 may continue to convey system coolant throughout system 100 while one or more tanks 300 are emptied, serviced and refilled, this process is described in further detail below.

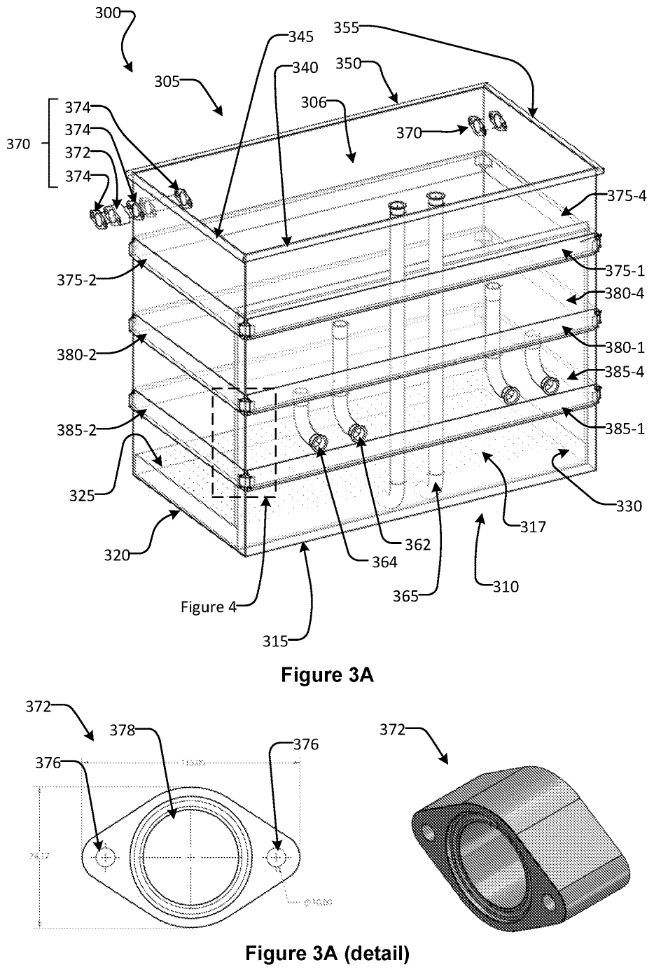

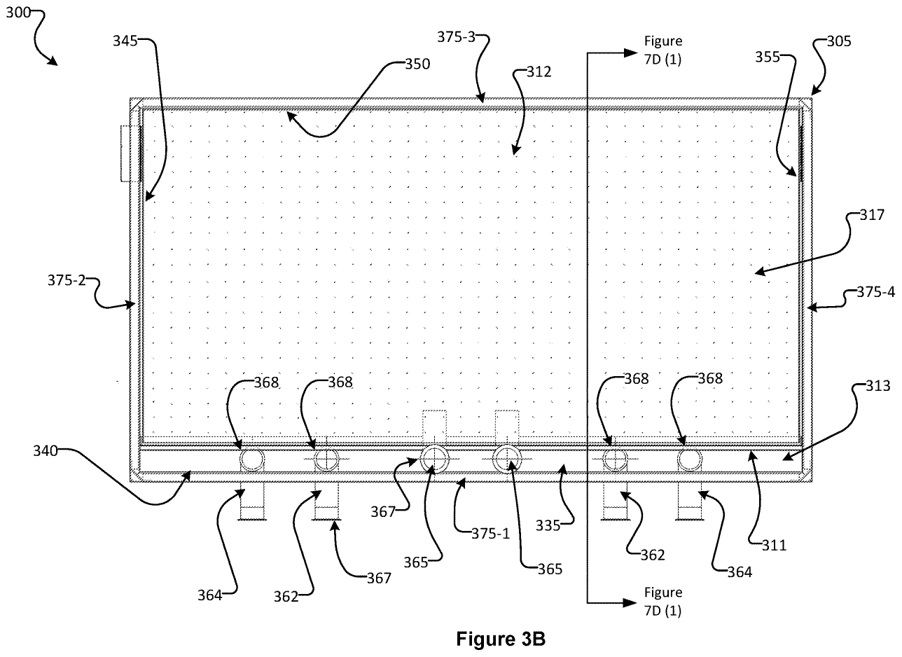

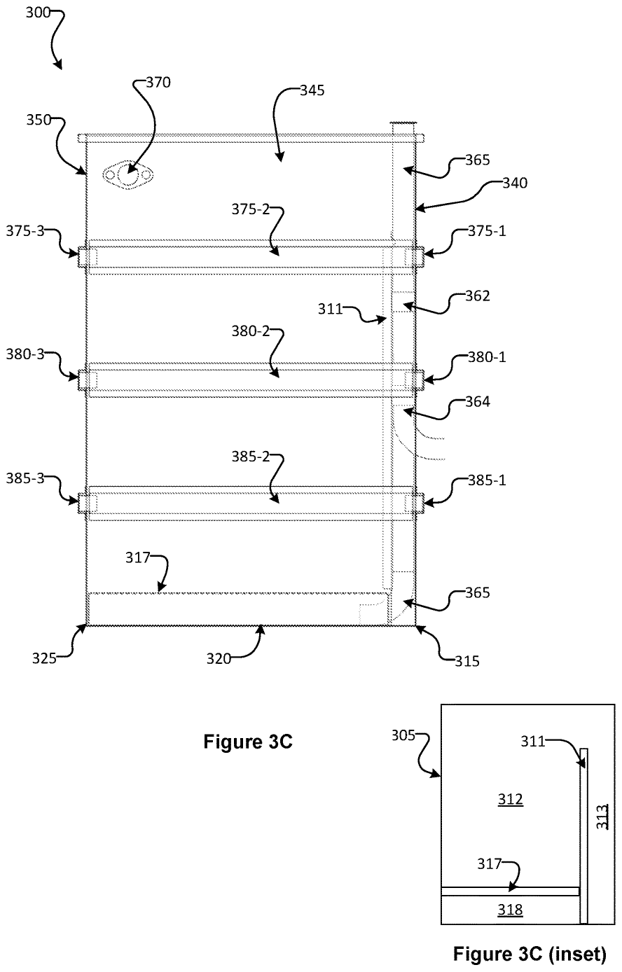

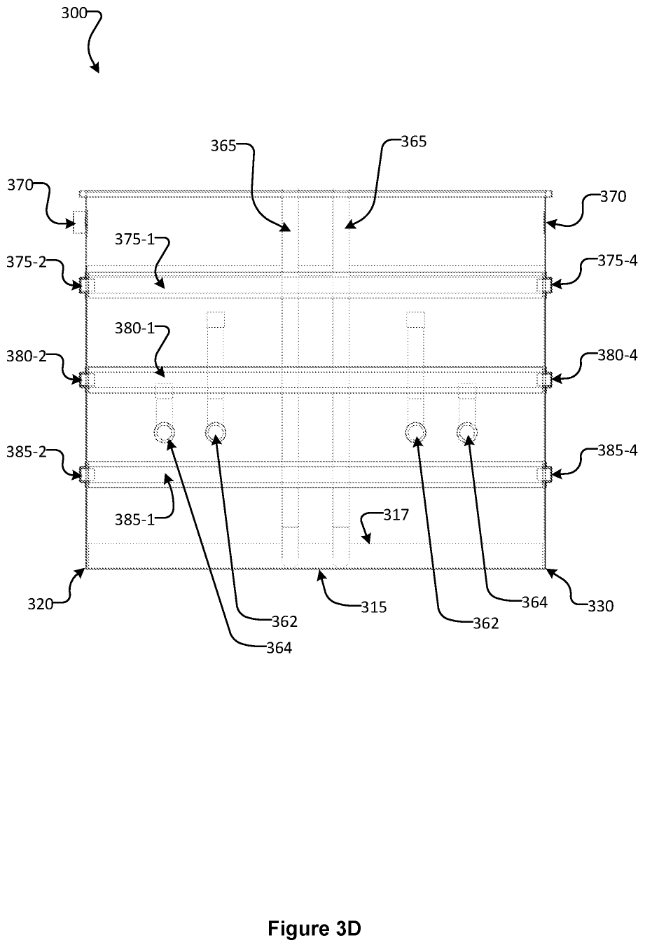

FIG. 3A to FIG. 3D are schematic diagrams of a cooling tank 300 that may be used in cooling system 100 as one of the cooling tanks 300 (see FIG. 1 and FIG. 2A). FIG. 3A illustrates a perspective view of cooling tank 300 according to some embodiments. FIG. 3B is a plan view of the cooling tank 300 according to some embodiments. FIG. 3C is a side view of the cooling tank 300 according to some embodiments. FIG. 3D is a front view of the cooling tank 300 according to some embodiments, wherein FIG. 3C is accordingly a view of the left side of the cooling tank 300.

Cooling tank 300 includes a container 305. The container 305 forms a working space to accommodate liquid coolant. In some embodiments, the container 305 comprises a plurality of connected walls which define an internal volume or cavity, which may be referred to as the working space. The container 305 may also comprise a first set of coolant conduits 362 and a second set of coolant conduits 365.

As shown in FIG. 3A, container 305 of cooling tank 300 comprises a bottom plate or panel 310 having a first edge 315, a second edge 320 adjacent to the first edge 315, a third edge 325 adjacent to the second edge 320 and opposite to the first edge 315, and a fourth edge 330 connecting the third edge 325 with the first edge 315. In some embodiments, the first edge 315 is a front-facing edge that is aligned with a front side of the container 305 (as viewed in FIG. 3D). In some embodiments, the third edge 325 is a rear-facing edge that is aligned with a rear side of the container 305. In some embodiments, the second edge 320 is left-facing edge and the fourth edge 330 is a right-facing edge that are disposed opposite each other and connect the front-facing and rear-facing edges of the bottom panel 310. The second edge 320 and the fourth edge 330 may be respectively aligned with a left side and a right side of the container 305.

Container 305 may further comprise a first side wall 340 extending from the first edge 315, a second side wall 345 extending from the second edge 320, a third side wall 350 extending from the third edge 325, and a fourth side wall 355 extending from the fourth edge 330. The side walls 340, 345, 350, 355 may be connected to each other and the bottom panel 310 to define the internal volume/working space of the container 305. The bottom panel 310 may define a base of the container 305. The side walls 340, 345, 350, 355 may define an opening 306 of the container 305. The opening 306 and the bottom panel 310 may be at opposite ends of the container 305. The first side wall 340 may be a front-facing wall, as viewed from the perspective shown in FIG. 3D. The third side wall 350 may be a rear-facing wall. The second side wall 345 and the fourth side wall 355 may be left-facing and right-facing walls that are disposed opposite each other and connect the front-facing wall 340 and rear-facing wall 350 of the container 305. The second side wall 345 and the fourth side wall 355 may be respectively aligned with a left side and a right side of the container 305.

The set of first coolant conduit 362 is configured to fluidly connect to the set of outlet pipes or outlet conduit 152 to convey the liquid coolant carrying the heat out of the cooling tank 300, such as shown in FIG. 2A for example. The set of second coolant conduits 365 are configured to fluidly connect to the inlet pipes 150 to supply liquid coolant to cooling tank 300.

Cooling tank 300 may include one or more sets of connection pipes 370. The set(s) of connection pipes may be configured to fluidly connect cooling tank 300 to one more adjacent cooling tanks, such as cooling tanks 300 (see FIG. 1 and FIG. 2A), to allow for balancing of liquid coolant levels across multiple adjacent cooling tanks 300. The connection pipes 370 may comprise a spacer 372, such as shown in FIG. 3A and in FIG. 3A's accompanying detail view. The spacer 372 may space apart the adjacent tanks 300. The connection pipes 370 allow for an uninterrupted overflow between adjacent connected tanks 300 in the event of major imbalance or overfill. The spacer 372 may be machined from billet aluminium and uses a viton gasket 374 to provide a seal between the spacer 372 and side of the tanks 300. The spacer 372 may define apertures 376 for receiving retaining bolts, which may be used to fix the spacer 372 into position. The spacer 372 may define a lumen 378 to allow the passage of the fluid through the spacer 372 between connected tanks 300. A connecting pipe (not shown) may fit within the lumen 378 for passage of the fluid. The spacer 372 may be approximately 115 mm long, 75 mm high, and 48 mm thick. The apertures 376 may have a diameter of approximately 10 mm. The lumen 378 may be approximately 65 mm in diameter. A plurality of concentric grooves may encircle the lumen 378 to accommodate a ring gasket. The spacer 372 may be diamond-shaped, wherein the apertures 376 are on either side of the lumen 378.

Cooling tank 300 may further comprise a separation panel 311 (shown in FIG. 3B), extending in the working space of container 305. The separation panel 311 is configured to separate the working space into a cooling space 312 and a return space 313. Separation panel 311 may extend from proximal to the bottom plate or panel 310, to proximal to the first reinforcing structure 375. In some embodiments, the separation panel 311 is connected to the bottom panel 310. In particular, separation panel 311 may extend approximately 960 mm from the bottom panel 310. In some embodiments, separation panel 311 may extend to the top of the tank 300. Computing devices 103 are placed in the cooling space 312 during operation. Separation panel 311 may be configured to control the flow and/or level of the coolant within the tank 300 or the container 305. The separation panel 311 may alternatively be referred to as a “weir wall” as it facilitates regulation of the fluid flow in the tank 300. The separation panel 311 may guide the flow of fluid in the tank 300. The separation panel 311 may determine the fluid level in the tank 300, particularly in the cooling space 312. The separation panel 311 may be removably connected to the container 305. In some embodiments, the separation panel 311 is welded to the container 305.

The cooling space 312 may be fluidly coupled to, or be in fluid communication with, the set of second coolant conduits 365. The return space 313 may be fluidly coupled to or be in fluid communication with the set of first coolant conduits 362. The separation panel 311 may be configured such that the liquid coolant in the cooling space 312 flows into the return space 313 due to supply of the liquid coolant into the cooling space 312 via the set of second coolant conduits 365. The set of first coolant conduits 362 may be further configured to convey the liquid coolant carrying the heat absorbed from the computing devices 103 out of the return space 313.

Turning now to FIG. 3C, the tank 300 may comprise perforated plate 317 which may be configured to further divide the working space of container 305 into the cooling space 312, the return space 313, and an inlet space 318. FIG. 3C (inset) is a simplified schematic of FIG. 3C, and shows how the perforated plate 317 and the separation panel 311 partition the working space into the cooling space 312, the return space 313, and an inlet space 318. In some embodiments, the perforated plate 317 partitions a portion of the cooling space 312 to define the inlet space 318. Inlet space 318 may be configured to receive new or otherwise comparatively cool liquid coolant via the set of second coolant conduits 365. The perforated plate 317 may be configured to facilitate circulation and/or even distribution of liquid coolant through and around cooling space 312.

The flow of the coolant through the tank 300 will now be described, according to an embodiment such as shown in FIG. 3C. The coolant enters the inlet space 318 via the conduits 365. As more coolant enters inlet space 318, it passes through the perforations in the perforated plate 317 and enters the cooling space 312 containing the computing devices 103. The coolant absorbs the heat emitted by the computing devices 103. The top of the separation panel 311 may be higher than the top of the computing devices 103 to allow for complete immersion of the computing devices 103. The top of the computing devices 103 may be around 25 mm below the top of the separation panel 311.

As more coolant enters inlet space 318 and subsequently the cooling space 312, the level of coolant in the cooling space 312 increases until it reaches the top of the weir wall/separation panel 311. More coolant entering the cooling space 312 causes the cooling space 312 to overflow with coolant, with the excess coolant flowing over the top of the weir wall/separation panel 311 and into the return space 313. This flow of coolant from the inlet space 318, through the cooling space 312, and into the return space 313 transfers heat away from the computing devices 103 in the cooling space 312. The heated coolant flows into the return space 313. The first coolant conduits 362 in the return space 313 receive the overflowing, heated coolant and transfers it to the heat dissipater 115 via the outlet conduit 152. The entry of the coolant conduit 362 is lower than the top of the separation panel 311. The exit of the coolant conduit 362 may be towards the bottom of the tank 300. The entry of the coolant conduit 362 being lower than the separation panel 311 reduces the likelihood of air entering the coolant conduit 362, thereby reducing the likelihood of undesirable vortexes developing in the flow of the coolant through the outlet conduits 152. During operation, the tank 300 may fill with coolant so that the coolant level in the cooling space 312 and the return space 313 is above the separation panel 311. The entry of the coolant conduit 362 may be below the coolant level in the return space 313. The flow of coolant into the tank 300 (via conduit 365) and/or the flow of coolant out of the tank 300 (via the conduit 362) may create a current or flow which encourages circulation of the coolant through the inlet space 318, cooling space 312, and return space 313.

The bottom panel 310, the first side wall 340, the second side wall 345, the third side wall 350, and the fourth side wall 355 form the working space. The set of first coolant conduits 362 and set of second coolant conduits 365 are located between the first side wall 340 and separation panel 311.

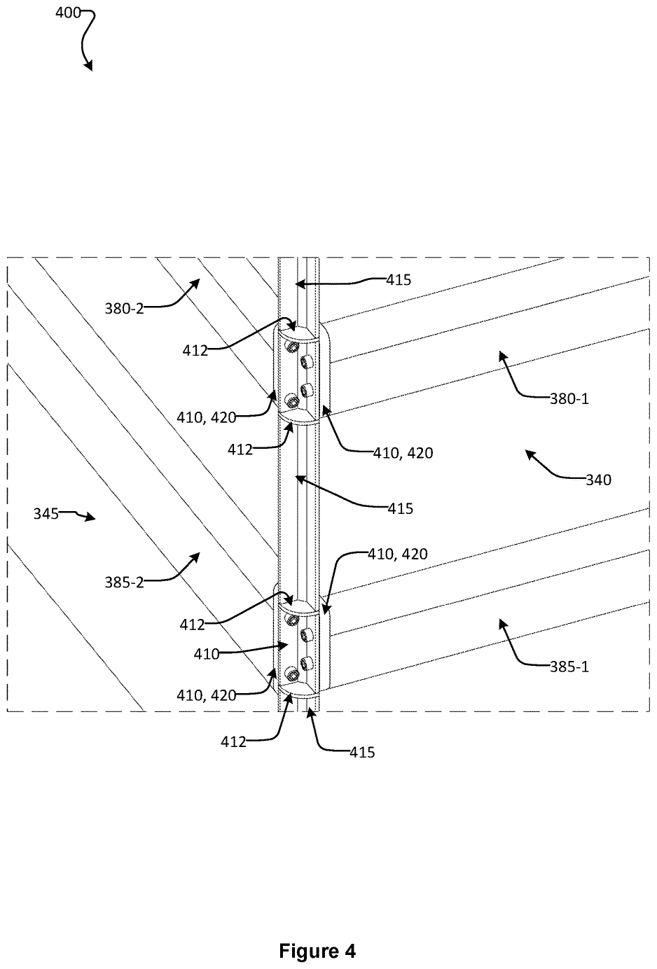

In some embodiments, at least one of the bottom panel 310, the first side wall 340, the second side wall 345, the third side wall 350, and the fourth side wall 355 are directly connected to each other, such as by welding each of the walls 340, 345, 350, 355 and the panel 310 to each other. In some embodiments, at least one of the bottom panel 310, the first side wall 340, the second side wall 345, the third side wall 350, and the fourth side wall 355 are indirectly connected to each other, such as via a supporting member or frame. In some embodiments, such as shown in FIG. 4, a vertical supporting member 415 may be affixed to the region where the first side wall 340 meets the second side wall 345, where the second side wall 345 meets the third side wall 350, where the third side wall 350 meets fourth side wall 355 and/or where the first side wall 340 meets the fourth side wall 355. The vertical supporting member 415 may extend substantially along the edge of side walls 340, 345, 350 and 355, extending substantially from the bottom plate or panel 310 to the top of tank 300. In some embodiments, side walls 340, 345, 350 and 355 may be affixed directly to vertical supporting members 415, whereby a vertical supporting member 415 forms each respective vertical edge of the outermost portion of the tank 300. In some embodiments, side walls 340, 345, 350 and 355 may be affixed to one another at their edges perpendicular to bottom panel 310, a vertical supporting member 415 may then be affixed to each of the edges of tank 300 perpendicular to bottom panel 310. The vertical supporting members 415 may be affixed to the edges of tank 300 perpendicular to bottom panel 310 by welding.

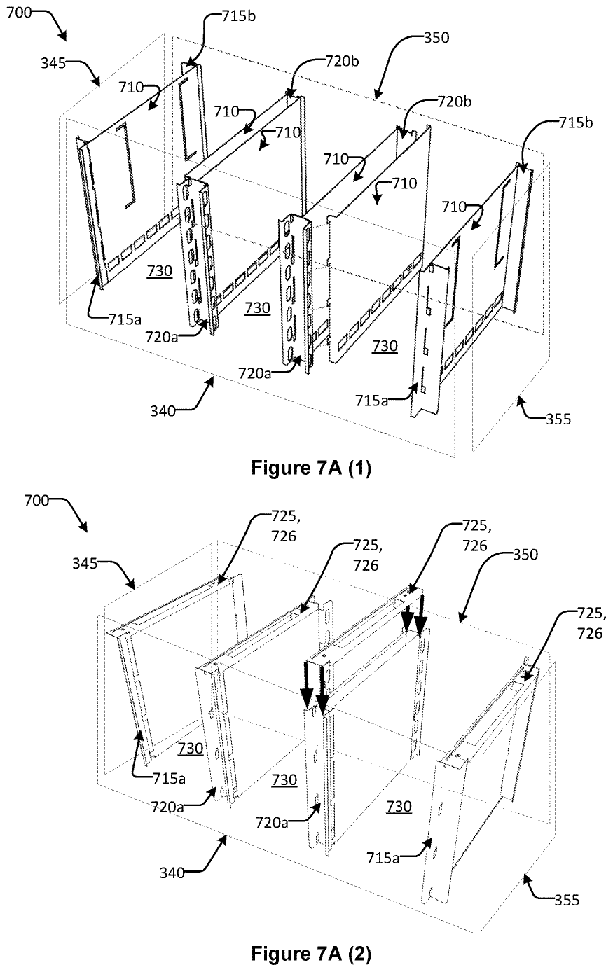

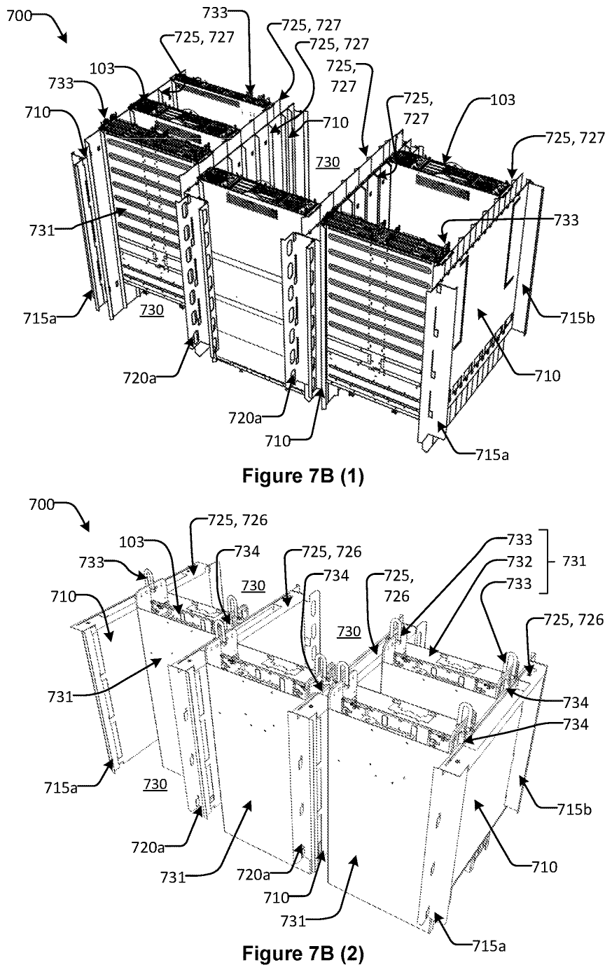

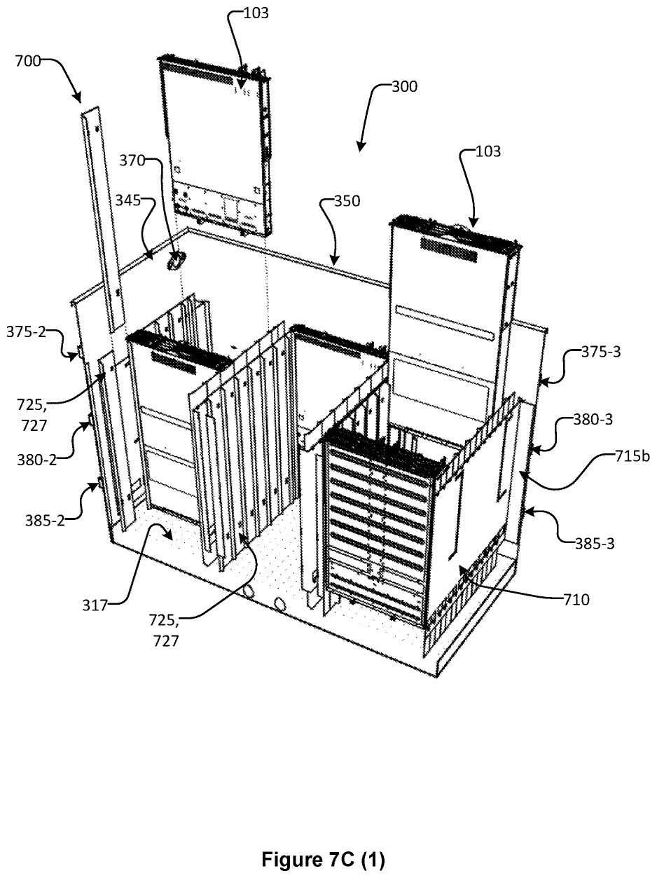

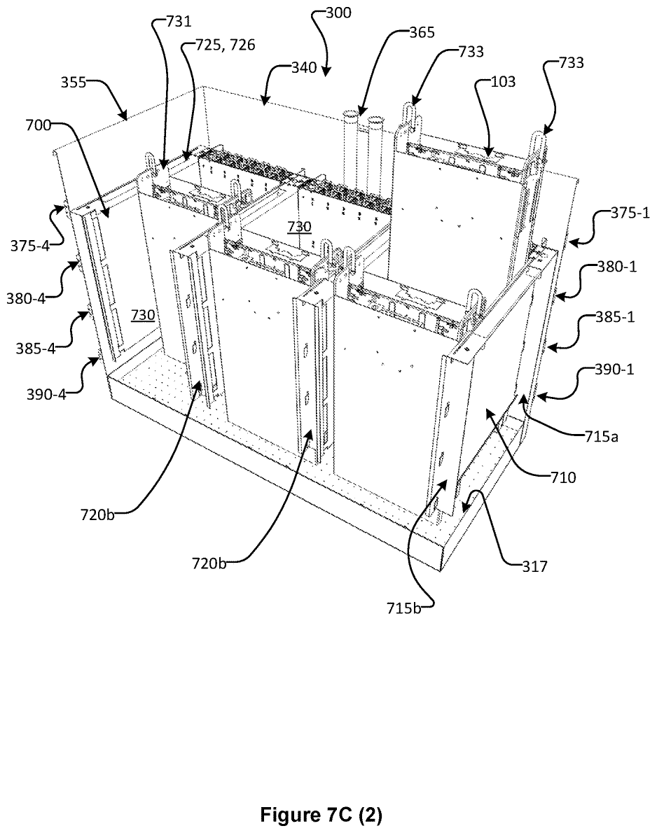

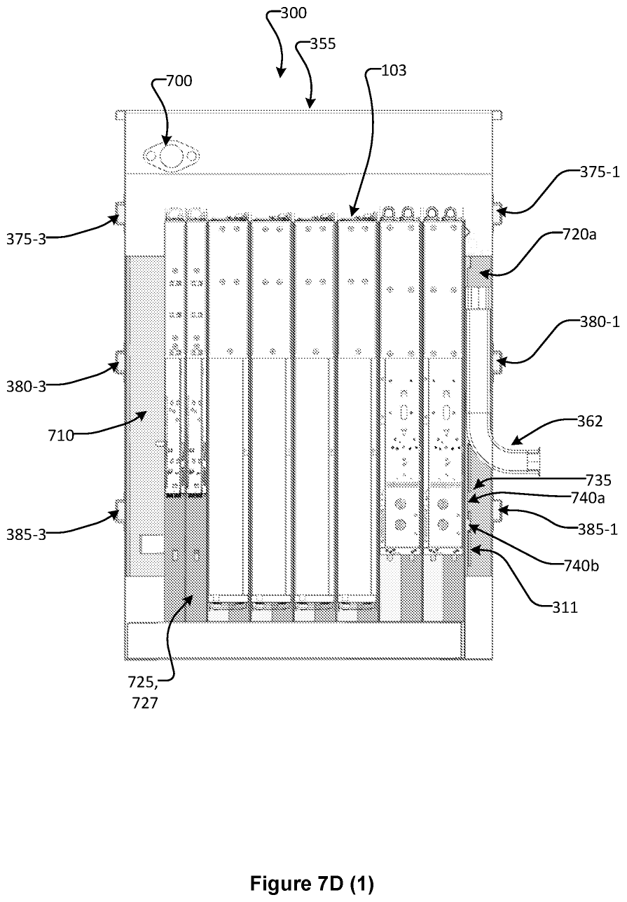

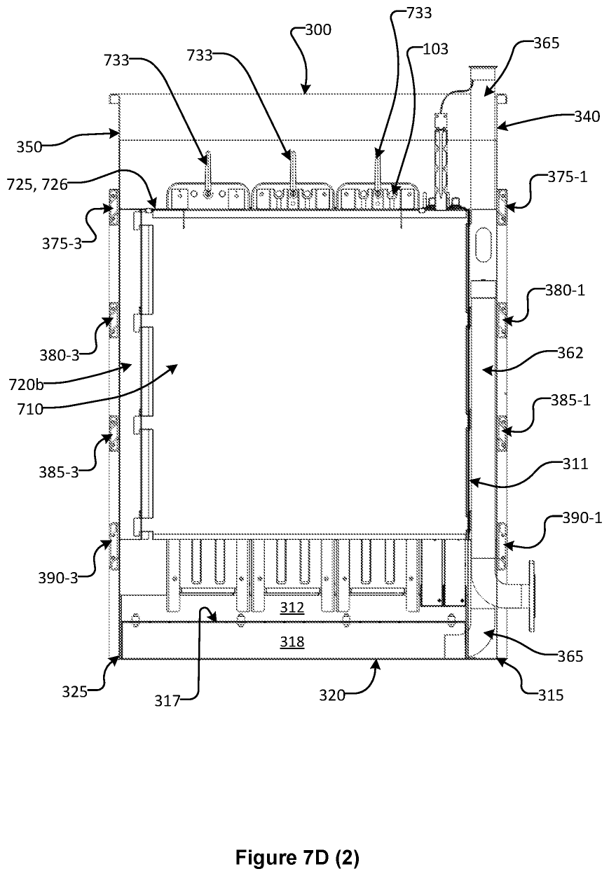

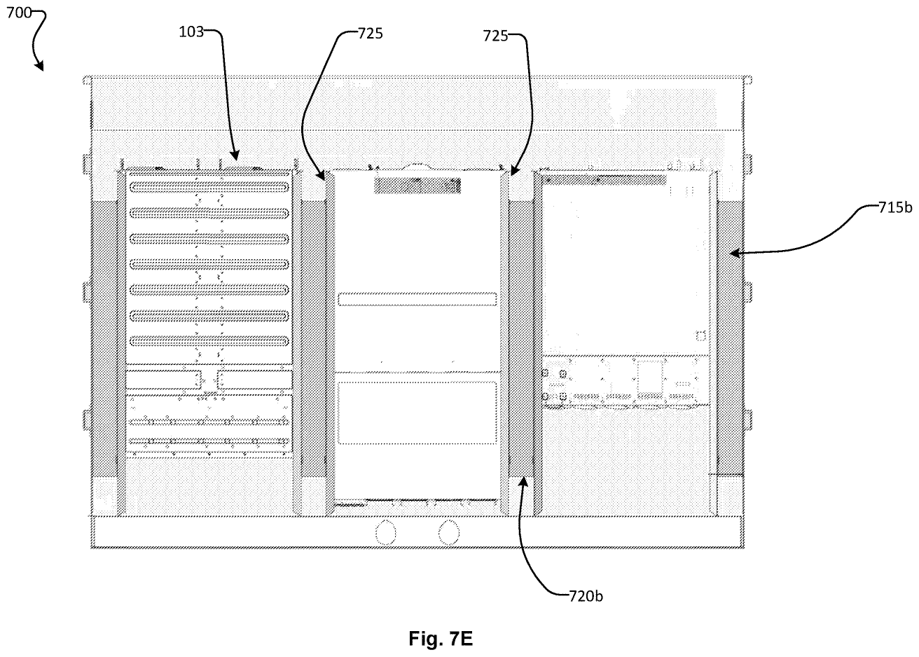

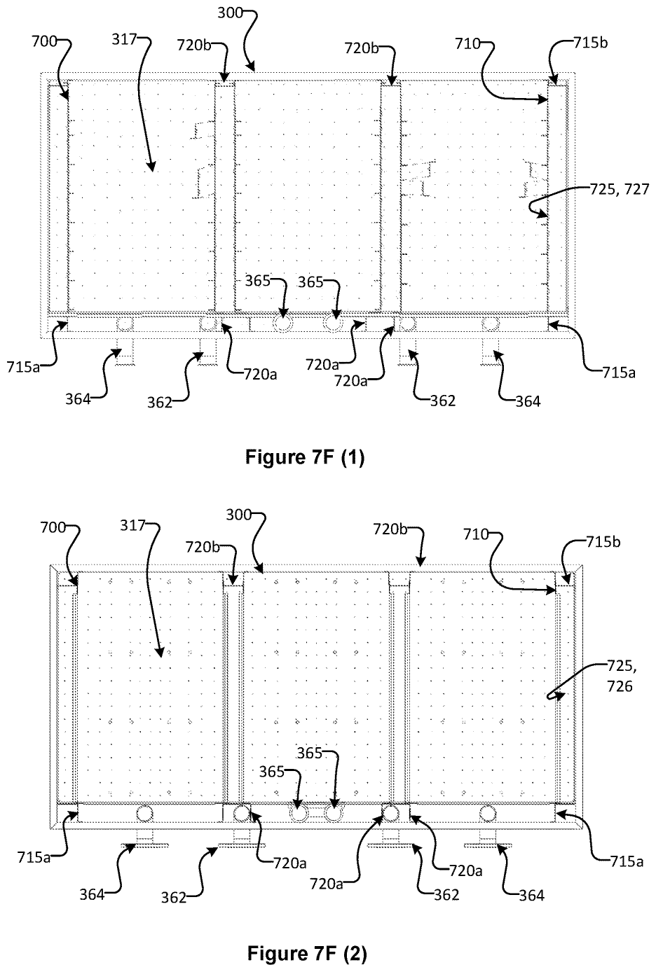

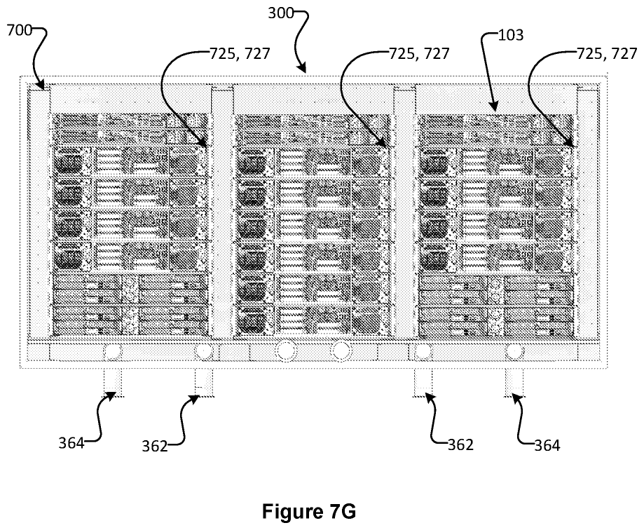

Turning again to FIGS. 3A-3D, the container 305 may be sized so as to receive a conventional rack unit (RU) server, such as shown by way of example in FIGS. 7C-7G. For example, first edge 315 of bottom panel 310 may have a length in the range 1500 mm to 1700 mm. First side wall 340, when positioned on bottom panel 310 as shown in FIG. 3A, may have a width of 1500 mm to 1700 mm. Third side wall 350 may have the same width as first side wall 340.

Second edge 320 of bottom panel 310 may have a length of 800 mm. Second side wall 345, when positioned on bottom panel 310 as shown in FIG. 3A, may have a width of 800 mm. Fourth side wall 355 may have the same width as second side wall 345.

First side wall 340, second side wall 345, third side wall 350 and/or fourth side wall 355, when positioned on bottom panel 310 as shown in FIG. 3A, may have a height in the range 1000 mm to 1200 mm. Each of side walls 340, 345, 350, and 355 may have the same height.

Container 305, bottom panel 310 and/or side walls 340, 345, 350, and 355 may be formed from stainless steel. In some embodiments, the container 305 and side walls 340, 345, 350, and 355 may be formed from stainless steel in separate processes and subsequently assembled or otherwise mated together to form tank 300. The container 305 and/or side walls 340, 345, 350, and 355 may be formed from another suitable material, such as aluminium, or a similar rust-resistant and/or corrosion resistant material. In some embodiments, container 305 and side walls 340, 345, 350, and 355 may be formed from different materials that are specifically suited to their particular purpose.

As shown in FIG. 3A-3D, tank 300 may comprise first reinforcing structure 375, second reinforcing structure 380 and/or third reinforcing structure 385. The first reinforcing structure 375, second reinforcing structure 380 and/or third reinforcing structure 385 may extend around the container 305 to brace the walls of the container 305. Referring now to FIG. 3A, the walls of the container 305 are shown in phantom to show how the first reinforcing structure 375, second reinforcing structure 380 and/or third reinforcing structure 385 extend around the container 305. In some embodiments, the first reinforcing structure 375 may comprise first rib 375-1, second rib 375-2, third rib 375-3 and/or fourth rib 375-4. Second reinforcing structure 380 may comprise first rib 380-1, second rib 380-2, third rib 380-3 and/or fourth rib 380-4. Third reinforcing structure 385 may comprise first rib 385-1, second rib 385-2, third rib 385-3 and/or fourth rib 385-4. The first ribs 375-1, 380-1, 385-1 may be disposed on the front-facing wall 340 of the tank 305. The second ribs 375-2, 380-2, 385-2 may be disposed on the side wall 345 (which may be a left side-facing wall) of the tank 305. The third ribs 375-3, 380-3, 385-3 may be disposed on the rear-facing wall 350 of the tank 305 (best seen in FIGS. 3B and 3C). The fourth ribs 375-4, 380-4, 385-4 may be disposed on the side wall 355 (which may be a right side-facing wall) of the tank 305.

The first reinforcing structure 375, the second reinforcing structure 380 and/or the third reinforcing structure 385 may be formed by fixing their individual component ribs together by bolting, welding and or gluing for example. The rib sections may be formed with a profile including z section, c section, top hat and/or box section. At least some of the ribs may be formed with a thickness in the range 1.6 mm to 3 mm. At least some of the ribs may be formed with a width in the range 50 mm to 100 mm. The dimensions of the ribs may be customised to suit the dimensions of an individual tank.

FIG. 4 is an image of mounting arrangement 400, according to some embodiments. Reinforcing structures 375, 380 and 385 may be affixed to one or more mounting brackets 410, which may be mounted to the vertical supporting member 415. At least one gusset plate 412 may be welded to the mounting bracket 410 and/or the vertical supporting member 415 to strengthen the vertical supporting member 415 against deflection. By way of example, FIG. 4 shows a left-front corner of the tank 300 (as marked on FIG. 3A) wherein the reinforcing structures 380-2, 385-2, 380-1 and 385-1 are connected to the vertical support member 415 via the mounting bracket 410. The vertical support member 415 may be an angle section. In some embodiments, vertical support member 415 may be a V-channel member, for example. In some embodiments, reinforcing structures 375, 380 and 385 are affixed to one or more mounting brackets 410, and abut against side walls 340, 345, 350, and 355, and may not be directly attached to side walls 340, 345, 350, and 355. This particular configuration may facilitate ease of assembly and/or disassembly. In some embodiments, reinforcing structures 375, 380, 385 may be affixed, either permanently or removably, to side walls 340, 345, 350, 355.

Each of the first ribs 375-1, 380-1, 385-1, second ribs 375-2, 380-2, 385-2, third ribs 375-3, 380-3, 385-3 and fourth ribs 375-4, 380-4, 385-4 may comprise mounting brackets 410 in the form of two end caps 420. End caps 420 may be affixed to the ends of each rib, perpendicular to the longitudinal axis of each rib. End caps 420 may be affixed to the ribs via welding. Each end cap may comprise a mating structure, such as a bolt receiving region, latching mechanism or a tab and slot arrangement. Mounting bracket 410 may comprise one or more matching and/or corresponding mating structure to interact with the mating structure of one or more end cap of one or more rib. When the mating structure of the mounting brackets 410 engages with the mating structure of the end caps, reinforcing structures 375, 380 and 385 may be formed and held in place around the tank 300. Reinforcing structures 375, 380, 385 may abut against side walls 340, 345, 350, and 355 of tank 300 and sit substantially parallel to the bottom panel 310.

Reinforcing structures 375, 380 and/or 385 may be formed around tank 300 by affixing each end of the first ribs 375-1, 380-1 and 385-1, second ribs 375-2, 380-2, 385-2, third ribs 375-3, 380-3 and 385-3 and fourth ribs 375-4, 380-4 and 385-4, via their respective end caps 420 to a respective mounting bracket 410. When formed around the tank 300, reinforcing structures 375, 380 and 385 may resist deflection of the walls of container 305 when the container 305 is filled with coolant.

Reinforcing structures 375, 380 and 385 may be positioned at different, predetermined distances relative to the bottom panel 310. For example, the centreline of first reinforcing structure 375 may be approximately 900 mm from the base of the bottom panel 310, the centre line of second reinforcing structure 380 may be approximately 600 mm from the base of the bottom panel 310 and/or the centre line of third reinforcing structure 385 may be approximately 300 mm from the base of the bottom panel 310.

The number of reinforcing structures formed around the tank may be in the range of 2 to 4. For example, there may be two reinforcing structures, three reinforcing structures, or four reinforcing structures formed around the tank. The structures may be evenly spaced for the tank depth. A tank having a depth of 1,200 mm for example may have three reinforcing structures at positioned at 300 mm, 600 mm and 900 mm respectively from the base of the tank and/or an upper edge of the tank.

When fully constructed, tank 300 may be approximately 1700 mm long, 800 mm wide and 1200 mm tall. In some embodiments, each tank 300 may be between 1000 mm and 3000 mm long. In some embodiments, each tank 300 may be between 400 mm and 2000 mm wide. In some embodiment, each tank 300 may be between 600 mm and 2000 mm tall. During normal operation, each tank 300 may be configured to hold between 1,000 and 2,000 L of cooling fluid. Each tank 300 may be configured to hold around 1,400 L of cooling fluid, for example. The tank 300 may be dimensioned to accommodate certain standardised sizes of computing device racking, such that there is sufficient space for multiple racking arrangements, multiple computing devices mounted within and/or outside the multiple racking arrangements, cabling, such as for power, data communication and/or temperature readings. For example, the tank may dimensioned to accommodate and/or interface with one or more power distribution unit (PDU) for supplying power and/or sending and receiving data from the computing devices. In some embodiments, the tank 300 may be dimensioned to accommodate more than one particular type of racking, computing device and/or cabling. The configuration of the racking is described in greater detail below.

In some embodiments, the tank 300 may be configured to hold approximately 1200 to 1400 litres of liquid coolant during operation. In some embodiments, the computing devices 103 disposed within the tank 300 may represent up to approximately 10% of the volume of liquid coolant held within the tank 300 during operation.

Referring again to FIG. 3A to FIG. 3D, the set of first coolant conduits 362 and set of second coolant conduits 365 may be positioned between separation panel 311 and first side wall 340. Tank 300 may also comprise a set of balance conduits 364, for use in isolating tank 300 when not in use. The set of first coolant conduits 362, set of second coolant conduits 365 and set of balance conduits 364 may be in contact with the first side wall 340 and the separation panel 311, such that the set of first coolant conduits 362, set of second coolant conduits 365 and set of balance conduits 364 may increase the rigidity of separation panel 311. As shown in FIG. 3B in particular, the set of first coolant conduits 362, set of second coolant conduits 365 and set of balance conduits 364, when in contact with first side wall 340 and the separation panel 311 act to reduce the span between mounting points of the separation panel 311, such as when the separation panel 311 is affixed to second container wall 345 and/or fourth container wall 355.

The first coolant conduits 362 may extend from the outside of the tank 300 to the inside of the container 305. For example, a first end of the first coolant conduits 362 may be disposed on the outside of the tank 300, while a second end of the first coolant conduits 362 may be disposed on the inside of the container 305. A first end of the first coolant conduits 362 may be located between the second reinforcing structure 380 and the third reinforcing structure 385 on the outside of the tank 300. In some embodiments, a first end of the set of first coolant conduits 362 may extend from proximal to third reinforcing structure 385, on the exterior of the tank 300, through the first side wall 340 into the interior of container 305. The first end of the first coolant conduits 362 may connect to the outlet conduit 152 to convey the heated liquid coolant out of the cooling tank 300, such as shown in FIG. 2A for example. In some embodiments, the set of first coolant conduits 362 may extend through first side wall 340 into return space 313. The set of first coolant conduits 362 may extend between separation panel 311 and first side wall 340, through the return space 313, away from bottom panel 310, and terminate proximal to a portion of separation panel 311 distal from bottom panel 310. The set of first coolant conduits 362 may comprise external connectors 367 and internal connectors 368. The external connectors 367 and/or internal connectors 368 may be one or more of a threaded end, a flange compatible end, a latching end, or a ferrule end. The external connectors 367 and internal connectors 368 may facilitate the connection of the first coolant conduits 362 and the outlet conduit 152.

The balance conduits 364 may extend from the outside of the tank 300 to the inside of the container 305. For example, a first end of the balance conduits 364 may be disposed on the outside of the tank 300, while a second end of the balance conduits 364 may be disposed on the inside of the container 305. A first end of the balance conduits 364 may be located between the second reinforcing structure 380 and the third reinforcing structure 385 on the outside of the tank 300. The first end of the balance conduit 364 for a first one of tank 300 may connect to the first end of the balance conduit 364 for a second one of tank 300, such as neighbouring ones of tanks 300. In some embodiments, a first end of the set of balance conduits 364 may extend from proximal to third reinforcing structure 385, on the exterior of the tank 300, through first side wall 340 into the interior of container 305. In some embodiments, the set of balance conduits 364 may extend through first side wall 340 into return space 313. The set of balance conduits 364 may extend between separation panel 311 and first side wall 340, through the return space 313, away from bottom panel 310, and terminate inside the return space 313, proximal to first rib 375-1. Balance conduit 364 may comprise external connectors 367 and internal connectors 368. The external connectors 367 and/or internal connectors 368 may be one or more of a threaded end, a flange compatible end, a latching end, or a ferrule end.

In some embodiments, the balance conduits 364 may be in fluidic connection with one or more balance conduits of one or more neighbouring tank(s) 300. In some embodiments, balance conduits 364 may be configured to account for flow variations and therefore liquid coolant volumes within and/or between different tanks 300 in system 100. Volumes of liquid coolant within tanks 300 may, over the extended course of operation varying from between 5% and 10% of total operation volume. For example, if the tank 300 has an operation liquid coolant volume of between 1,200 L and 1,400 L, the actual volume of liquid coolant within the tank 300 may be between 1,080 L to 1,580 L.

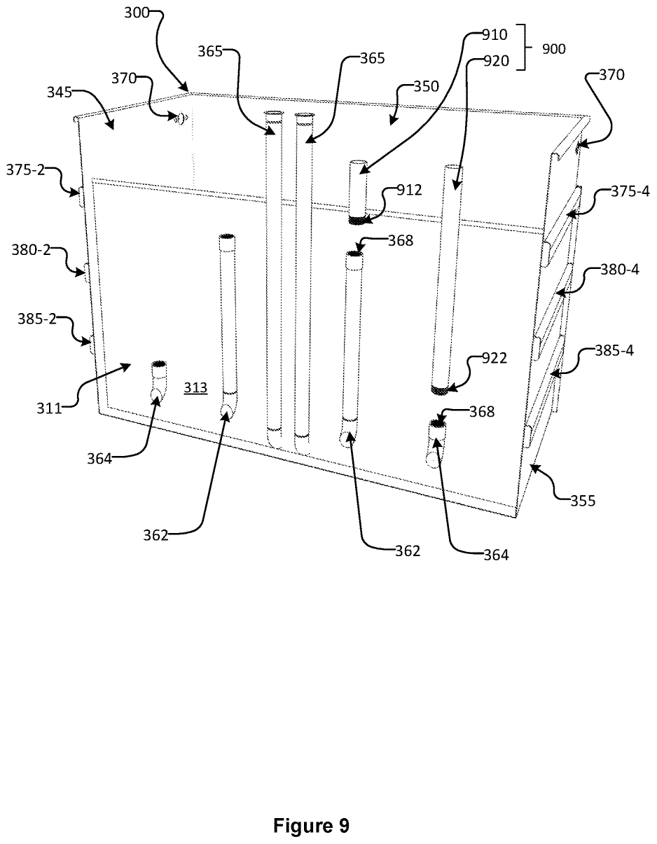

In some embodiments, the balance conduits 364 may be configured to isolate the tank 300 from one or more neighbouring tanks and/or the rest of the system 100. To isolate tank 300 from the rest of system 100 and neighbouring tanks, balance conduits 364 may be sealed using a plug such as a threaded plug, which may be fed between separation panel 311 and first side wall 340 and engages with a threaded end of balance conduit 364. For example, the first end of the balance conduits 364 (accessible from the exterior of the tank 300) may comprise at least one of the external connectors 367 and the internal connectors 368. The plug 900 is shown in FIG. 9. For clarity, FIG. 9 shows the tank 300 without front wall 340, so that separation panel 311 and the conduits 362, 364, 365 can be seen. For the avoidance of doubt, the front wall 340 is otherwise present. During operation, the front wall 340 is present. The plug 900 may comprise a coolant conduit plug 910 for the coolant conduit 362. The plug 900 may comprise a balance conduit plug 920 for the balance conduit 364. The plugs 910, 920 may comprise a corresponding mating feature 912, 922 which is configured to engage with the external connector 367 and/or internal connector 368 to seal the first end of the balance conduits 364 and thereby isolate the tank 300. In some embodiments, the external connector 367 and/or internal connector 368 comprises a thread which is configured to engage with a corresponding thread on the plug. When the plugs 910, 920 are connected to their respective conduits 362, 364, the openings to the conduits 362, 364 are sealed so that coolant in the return space 313 cannot enter the conduits 362, 364. The plugs 910, 920 may extend the opening of the conduits 362, 364 to above the top of the separation panel 311 to reduce the likelihood of coolant entering the conduits 362, 364. In particular, the plugs 910, 920 may extend the opening of the conduits 362, 364 to above the top of the fluid in the tank 300 to reduce the likelihood of coolant entering the conduits 362, 364.

Turning again to FIGS. 3A-3D, in some embodiments, the second set of coolant conduits 365 may extend from the open portion or opening 306 of the tank, distal from bottom panel 310, into container 305. In some embodiments, the second set of coolant conduits may extend between separation panel 311 and first side wall 340, through return space 313. The set of second coolant conduits 365 may pass through perforated plate 317 and bend, at about a right angle, to run substantially parallel to the bottom panel 310 away from first side wall 340, through inlet space 318. The set of second coolant conduits 365 may terminate substantially proximal to first side wall 340.

In some embodiments, the tank 300 may comprise one or more characterised ball valves 360 (not shown in FIGS. 3A-3D; shown in FIG. 2A), configured to adjust or otherwise control the flow of liquid coolant into and/or out of tank 300 and/or where to and/or from the liquid coolant flows within system 100. Characterised ball valves 360 may be mated to one or more first coolant conduits 362, and/or second coolant conduits 365, for example characterised ball valves 360 may be attached to conduits 362, 365 via a flange arrangement, tri-clover/ferrule arrangement or by welding.

The characterised ball valves 360 may be configured to alter the amount of flow through the valve through a turning mechanism, wherein the degree a valve handle or tap is turned correlates directly to the degree of flow impedance. For example, if the valve handle is turned 50% from the open position towards the closed position, the flow of liquid coolant through the valve will be reduced by 50%. In another example, if the valve handle is turned 30% from the open position towards the closed position, 30% of the flow will be impeded, allowing 70%

In some embodiments, the tank 300 may be covered, completely or partially, by an insulating layer. The insulating layer may be configured to reduce heat leakage from the liquid coolant contained within the tank 300, and the external space the tank 300 is situated in. The insulating layer may comprise insulation, such as Thermobreak insulation. Stopping or otherwise reducing the amount of heat energy radiating from the tank 300 may aid in flow rate calculations, as when the temperature of the coolant while in the tank 300 is known and/or can be accurately calculated, flow rates for the entire system 100 may be more easily and/or accurately calculated. Reducing heat radiation may also aid in keeping a server room at a comfortable working temperature.

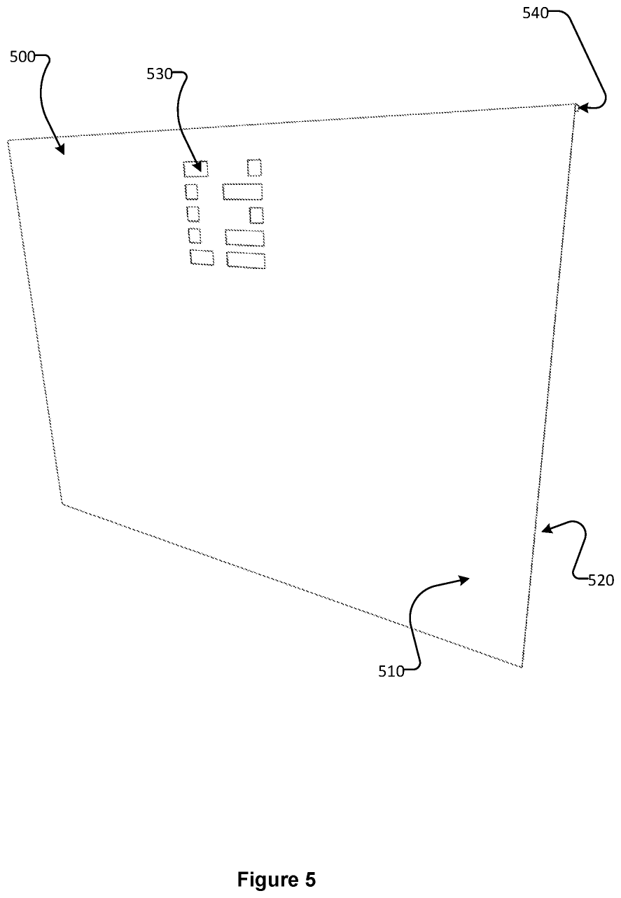

FIG. 5 is an image of exterior cladding panel 500, according to some embodiments. The cladding panel 500 comprises a sheet defining an outer face 510 and an inner face 520 opposite the outer face 510. The inner face 520 may face a wall of the container 305, while the outer face 510 faces away from said wall. The sheet may define at least one aperture 530 extending between the outer face 510 and the inner face 520. The aperture 530 may be configured to allow heat from the container 305 to pass through the cladding panel 500. The aperture 530 may be configured to allow a user to view the container 305 through the aperture 530, for example for maintenance purposes. The aperture 530 may be configured to allow a user to hold the panel 500. The cladding panel 500 may comprise a ridge 540 at one end of the panel 500. The ridge 540 may be defined on the inner face 520 of the panel 500. The ridge 540 may be configured to engage with a correspondingly shaped and sized groove (not shown) on the container 305, thereby allowing the panel 500 to be affixed to the container 305. The cladding panel 500 may define mounting apertures to allow a removable fastener such as a bolt or screw to secure the panel 500 to the container 305.

In some embodiments, tank 300 may comprise exterior cladding panel 500. Exterior cladding panel 500 may be affixed to first side wall 340, second side wall 345, third side wall 350 and/or second side wall 355. Exterior cladding 500 may be formed from stainless steel, or any other light weight durable and/or corrosion resistant material. The tank 300 may comprise one or more exterior cladding panels 500. The exterior cladding panels 500 may be affixed by welding, bolting, latching and/or tab and slot arrangement, for example. The exterior cladding panel 500 may be made from 1.6 mm stainless steel. The exterior cladding panel 500 may be powder coated for protection and/or aesthetic purposes. There may be insulation positioned between the exterior cladding panel 500 and at least one of the walls 340, 345, 350, 355, wherein the respective cladding panel 500 and the respective tank walls are spaced apart to receive the insulation. Insulation material may include, for example, physically crosslinked closed cell polyolefin foam with factory applied reinforced aluminium foil. The insulation may be high density foam with an aluminium tape backing. The insulation may be sisal faces high density foam insulation with reinforced silver tape. The insulation may be 20 mm thick. The insulation may be added to the outside of the tank 300, with the cladding panel 500 added on top of the insulation. The combination of the insulation and exterior cladding panel 500 may provide a thermal barrier around the tank 300 which reduces the heat loss of the system.

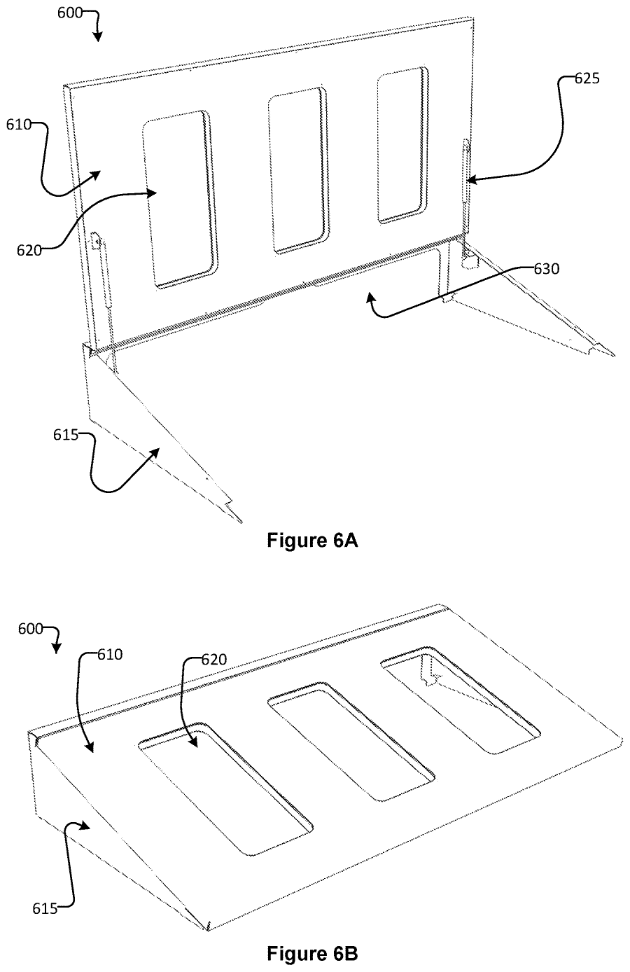

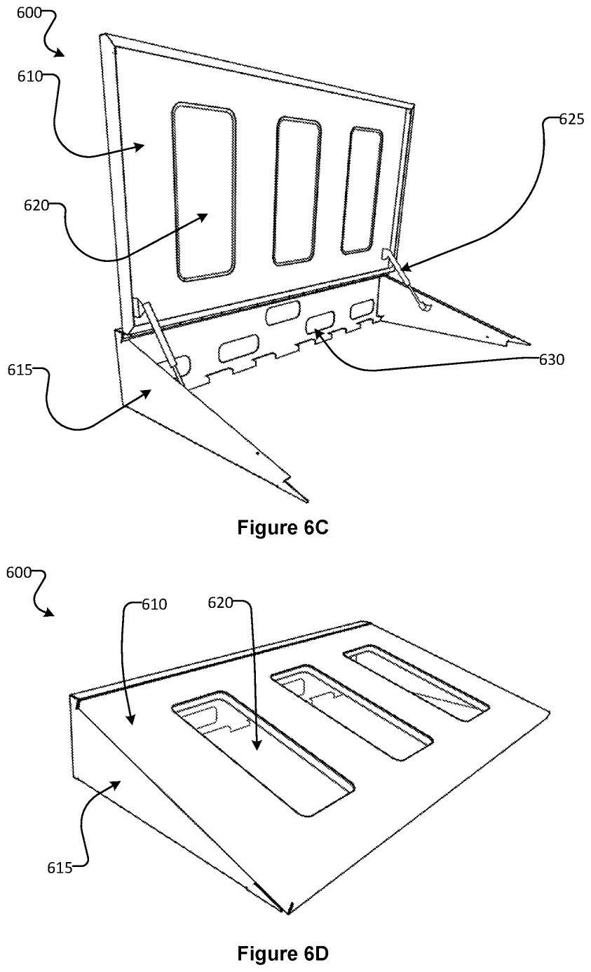

FIGS. 6A, 6B, 6C and 6D are images of a covering 600 for tank 300 (not shown). Covering 600 may be secured or otherwise placed over the opening 306 of tank 300, distal from the base of the tank 300 (for example, bottom panel 310), such as shown in FIG. 2A. Covering 600 may comprise lid portion 610, cover mounting portion 615, one or more viewing windows 620, one or more actuation mechanisms 625 and/or cable management aperture 630. The cable management aperture 630 may comprise a single large aperture as shown in FIGS. 6A and 6B. In some embodiments, the cable management aperture 630 comprises multiple apertures, such as shown in FIGS. 6C and 6D. Lid portion 610 may be hingedly connected to cover mounting portion 615. In some embodiments, lid portion 610 may not be connected to cover mounting portion 615. Cover mounting portion 615 may be affixed to tank 300 by a bolt arrangement, clasp arrangement, welding, or tab and slot mechanism, for example. As exemplified by FIG. 6A, the one or more actuation mechanisms 625 may be pneumatic pistons, connected to both lid portion 610 and cover mounting portion 615. The one or more actuation mechanisms 625 may be configured to aid in the opening and/or closing of the lid portion 610. In some embodiments, lid portion 610 may comprise one or more viewing windows 620. Viewing windows 620 may be configured to allow inspection of the one or more computing devices 103 (not shown), mounted in one or more rack arrangements, disposed inside the tank 300. In some embodiments, viewing windows 620 may comprise glass or acrylic windows, or no glass or acrylic at all. In some embodiments, lid portion 610 may comprise the same number of viewing windows 620 as there are computing device racks disposed inside tank 300. In some embodiments, lid portion 610 may comprise a single viewing window 620 that is configured to allow viewing of all computing devices disposed inside tank 300.

FIGS. 7A, 7B, 7C, 7D, 7E, 7F and 7G are schematic diagrams of a racking system 700, which may be used for supporting at least one of the computing devices 103 inside the tank 300, according to some embodiments. FIG. 7A is a perspective view of racking system 700, wherein FIG. 7A (1) shows one embodiment of the racking system 700 and wherein FIG. 7A (2) shows another embodiment of the racking system 700. FIG. 7B is a perspective view of racking system 700 with computing devices 103 disposed therein, wherein FIG. 7B (1) shows one embodiment of the racking system 700 and wherein FIG. 7B (2) shows another embodiment of the racking system 700. FIG. 7C is a perspective view of the racking system of FIG. 7B, disposed inside tank 300 (tank 300 shown in part for clarity), wherein FIG. 7C (1) shows one embodiment of the racking system 700 and wherein FIG. 7C (2) shows another embodiment of the racking system 700. FIG. 7D is a section view of tank 300, showing racking system 700 within the tank 300, wherein FIG. 7D (1) shows one embodiment of the racking system 700 and wherein FIG. 7D (2) shows another embodiment of the racking system 700. FIG. 7E is a front view of racking system 600. FIG. 7F is a plan view of the racking system 700, wherein FIG. 7F (1) shows one embodiment of the racking system 700 and wherein FIG. 7F (2) shows another embodiment of the racking system 700. FIG. 7G is a plan view of the racking system of FIG. 7F with computing devices 103 disposed therein.

Referring now to FIG. 7A (1) and FIG. 7A (2), racking system 700 may comprise rack mounting members 710 and/or rack securing members 715a, 715b, 720a, 720b. Rack mounting members 710 may be configured to receive one or more computing device mounting member 725 (as shown in FIG. 7A (2), FIG. 7B (1) and FIG. 7B (2)), for mounting computing devices 103. Rack mounting members 710 may be in connection with rack securing members 715a, 715b, 720a, 720b. The rack securing members 715a, 715b, 720a, 720b may be disposed within the container 305 of the tank 300. Each of the rack securing members 715a, 715b, 720a, 720b may be connected to at least one of the side walls 340, 345, 350, 355 of the container 305. FIG. 7A includes a simplified, dashed outline of the side walls 340, 345, 350, 355 to show their approximate position relative to the rack securing members 715a, 715b, 720a, 720b. The rack mounting members 710 are spaced apart within the tank 300 to define a bay 730 between each pair of adjacent rack mounting members 710. The bay 730 is configured for receiving the computing devices 103.

Rack securing member 715a may be a corner member that is configured to connect to two adjacent side walls. For example, a first one of the rack securing member 715a is configured to connect to side walls 340 and 345, and a second one of the rack securing member 715a is configured to connect to side walls 340 and 355.

Rack securing member 715b may be a corner member that is configured to connect to two adjacent side walls. For example, a first one of the rack securing member 715b is configured to connect to side walls 345 and 350, and a second one of the rack securing member 715b is configured to connect to side walls 350 and 355. The rack securing members 715a may be disposed towards a front side of the tank 300 (such as front side wall 340), while the rack securing members 715b may be disposed towards a rear side of the tank 300 (such as rear side wall 350). Rack securing members 720a may be configured to connect to side wall 340, and rack securing members 720b may be configured to connect to side wall 350. The rack securing members 715a, 715b, 720a, 720b may also be referred to herein as first racking members 715a, 715b, 720a, 720b. The rack securing members 715a, 715b, 720a, 720b may be angle sections. At least one of the angle sections may define a plurality of perforations or slots configured to receive a connector along the length of the angle section. The rack securing members 715a, 715b may be a first type of angle section that is different from the angle sections used for 720a, 720b. For example, the angle section used for rack securing members 715a, 715b may be substantially L shaped, while the angle section used for rack securing members 720a, 720b may be substantially U shaped.

Rack mounting members 710 may connect to either rack securing members 715a and 715b, or to rack securing members 720a and 720b. The rack mounting members 710 may be a plate or sheet of metal defining perforations. The rack mounting members 710 may also be referred to herein as second racking members 710. Each one of the rack mounting members 710 may connect to at least two of the rack securing members 715a, 715b, 720a, 720b. For example, a first end of the rack mounting member (second racking member) 710 is connected to the rack securing member (first racking member) 715a, and a second end of the rack mounting member (second racking member) 710 is connected to the rack securing member (first racking member) 715b.

In some embodiments, the rack securing members (first racking members) 715a and 715b receives one of the rack mounting members (second racking members) 710. In some embodiments, the rack securing members (first racking members) 720a and 720b receives two of the rack mounting members (second racking members) 710. When connected, rack mounting members 710 and rack securing members 715a, 715b, 720a, 720b may increase the structural strength of tank 300 by forming a support structure for the container 305. The support structure may reduce the unsupported span of the tank side wall 340, 345, 350, 355 and/or connect the side walls to each other, thereby resisting deflection of side walls 340, 345, 350, 355 when the container 305 is filled with liquid coolant. Tank 300 may be dimensioned to accommodate racking systems configured to mount 900 mm deep computing systems, such as servers.

As shown in FIG. 7A (2), FIG. 7B (1) and FIG. 7B (2), the rack mounting members 710 may be configured to receive a plurality of computing device mounting members 725. The computing device mounting members 725 may also be referred to herein as third racking members 725.

With reference to FIG. 7A (2) and FIG. 7B (2), in some embodiments the computing device mounting member 725 comprises a cover plate 726. According to some embodiments, such as shown in FIG. 7A (2), the cover plate 726 comprises a slot and at least one aperture. The cover plate 726 is configured to engage with at least one of the rack mounting members (second racking members) 710 and its associated rack securing members (first racking members) 715a, 715b, 720a, 720b. The cover plate 726 may be placed on top of the rack mounting members 710 to brace the rack mounting members 710.

FIG. 7A (2) shows a partly assembled view, with one of the cover plate 726 about to be lowered into position on top of the rack mounting members 710 as indicated by the bold arrows. The cover plate 726 may receive or support a portion of the computing devices 103 when the computing devices 103 are received and mounted in the tank 300.

FIG. 7B (2) shows an assembled view wherein all of the cover plates 726 are in position on top of the rack mounting members 710. FIG. 7B (2) shows computing devices 103 received in the bay 730 between adjacent second racking members 710. In some embodiments, the computing devices 103 comprise a chassis or casing 731. The casing 731 may enclose the components 732 of the computing device 103. The components 732 may include central processing units (CPUs), graphical processing units (GPUs), random access memory (RAM) and/or motherboard chipsets. The casing 731 may comprise at least one open end to allow coolant to enter and pass through the casing 731. The casing 731 may comprise at least one lifting lug 733 connected to the casing 731. The lifting lug 733 is configured to enable to casing 731 (and computing device 103 therein) to be lowered into the tank 300 and positioned into bay 730, such as by a crane or winch. The lifting lug 733 may be aligned with a centre of gravity of the computing device 103 so that when the casing 731 (and computing device 103 therein) are lifted, the casing 731 remains in an upright orientation that allows the casing 731 to be directly lowered into the bay 730 with minimal or zero tilting or other angular realignment to mount the casing 731. When a plurality of the casings 731 are received in the bay 730, adjacent ones of the casing 731 may abut each other. The casing 731 may comprise a clip 734 that is configured to engage with the cover plates 726 when the casing 731 is within the bay 730. The clip 734 may be configured to engage with the slot in the cover plate 726.

With reference to FIG. 7B (1), in some embodiments, the computing device mounting member 725 comprises guide member 727. The guide members 727 may be arranged to effectively divide the bay 730 into designated spaces for receiving each one of the computing devices 103. The guide members 727 may resemble fins or ridges that extend into the bay 730 but do not extend across the entirety of the bay 730 defined between adjacent rack mounting members 710. A plurality of the guide members 727 may be installed on the rack mounting members 710 in a vertical configuration corresponding to the number of designated spaces. The guide members 727 are configured to guide the computing devices 103 as the computing devices 103 are lowered (via lifting lugs 733) into their designated spaces. The guide members 727 may space apart the computing devices 103 in the bay 730. The guide members 727 may abut the casing 731 containing the computing devices 103.

Computer device mounting members 725 may be configured to interface with rack mounting members 710 via a tab and slot arrangement, friction fit arrangement and/or screw and fastener arrangement, for example. Rack mounting members 710 may be configured to receive a plurality of different sizes and/or configurations of computing device mounting members 725, such as standard rack unit (RU) computing device racks and/or RU computing devices and/or application-specific integrated circuit (ASIC) computing devices and/or ASIC computing device racking. Racking system 600 may comprise a plurality of rack units, each rack unit comprising at least one rack mounting member 710, and at least a pair of rack securing members 715a, 715b, 720a, 720b.

FIG. 7C (1) shows a perspective view of the tank 300 containing racking system 700. FIG. 7C shows only part of the tank 300 to allow the racking system 700 and the computing devices 103 to be seen. Specifically, the side walls 345 and 350 are shown, with side walls 340 and 355 removed. Separation panel 311 is also not shown.

FIG. 7C (1) shows an embodiment of the racking system 700 in a partially exploded assembly view. The racking system 700 comprises the guide members 727 for the computing devices 103. The guide members 727 may contact the perforated plate 317 at the bottom of the container 305.

FIG. 7C (2) is a perspective view of the tank 300, from the reverse angle to FIG. 7C (1). FIG. 7C (2) shows another embodiment of the racking system 700 in a tank 300, according to some embodiments. This embodiment of the tank 300 has a fourth reinforcing structure 390, which is similar to the aforementioned reinforcing structures 375, 380, 385. The fourth reinforcing structure 390 accordingly has ribs 390-1, 390-2 (not shown with side wall 345 removed), 390-3 (not shown with side wall 350 removed), and 390-4.

As shown in FIG. 7D, in some embodiments, separation panel 311 may define a plurality of regions configured for rack mounting members 710 and rack supporting members 715a, 720a or sections there-of, to pass there-through. Rack supporting members 715a, 720a may be affixed to first wall 340, and comprise mating structure 740a. Rack mounting members 710 may comprise a corresponding mating structure 740b, configured to interface with mating structure 740a. Mating structures 740a, 740b may pass through regions 735 and interface to secure rack support member 710 to rack support member 720a, 720b.

FIG. 7D (1) is a section view of the tank 300 parallel to the side wall 355 of the tank 300, in the approximate location marked on FIG. 3B. FIG. 7D (1) shows an embodiment of the racking system 700 comprising the third racking members 725, in particular the guide members 727. The computing devices 103 are aligned vertically by the guide members 727.

FIG. 7D (2) is a section view of the tank 300 from a similar location as FIG. 7D (1), except coolant conduit 365 is shown. FIG. 7D (2) shows an embodiment of the racking system 700 comprising the third racking members 725, in particular the cover plate 726. The computing devices 103 abut the cover plate 726. The computing devices 103 may be spaced apart from the perforated plate 317 so as not to cover the perforations and potentially impede the flow of the coolant from the inlet space 318 into the cooling space 312.

As shown in FIG. 7B and FIG. 7C, each computing device mounting member 725 may have an adjacent corresponding computing device mounting member 725. Computing device 103 may be received within each of the corresponding computing device mounting members 725. In some embodiments, corresponding computing device mounting members 725 may have a similar configuration. In some embodiments, corresponding computing device mounting members 725 may have different configurations to accommodate asymmetrical computing devices. In some embodiments, computing device mounting members 725 may comprise one or more mounting points (not shown), for interaction with computing devices 103.

As depicted in FIGS. 7C, 7D and 7E, computing systems 103 may be mounted in a vertical orientation. That is to say, the longitudinal axis of computing devices 103 may be substantially parallel to first side wall 340.

As shown in FIGS. 7C, 7D and 7E, the ends of the computing devices 103 that are distal to bottom plate or panel 310 may be positioned substantially below the opening 306 or the upper portion of tank 300 that is distal from bottom plate or panel 310. This configuration is to ensure that the computing devices 103 are easily and/or continuously submerged within the liquid coolant.

FIG. 7F (1) is a plan view showing an embodiment of the racking system 700 in the tank 300. The embodiment of the racking system 700 as shown comprises the third racking members 725, in particular the guide members 727. FIG. 7G shows the same view, with computing devices 103 within the tank 300.

FIG. 7F (2) is a plan view showing an embodiment of the racking system 700 in the tank 300. The embodiment of the racking system 700 as shown comprises the third racking members 725, in particular the cover plate 726.

In some embodiments, the racking system 700 is connected to at least one of the side walls 340, 345, 350, 355. In some embodiments, the racking system 700 is connected to the separation panel 311. In some embodiments, the racking system 700 is connected to both the separation panel 311 and at least one of the side walls 340, 345, 350, 355. For example, in embodiments where the separation panel 311 is removable, the racking system 700 is connected to the side wall 340.

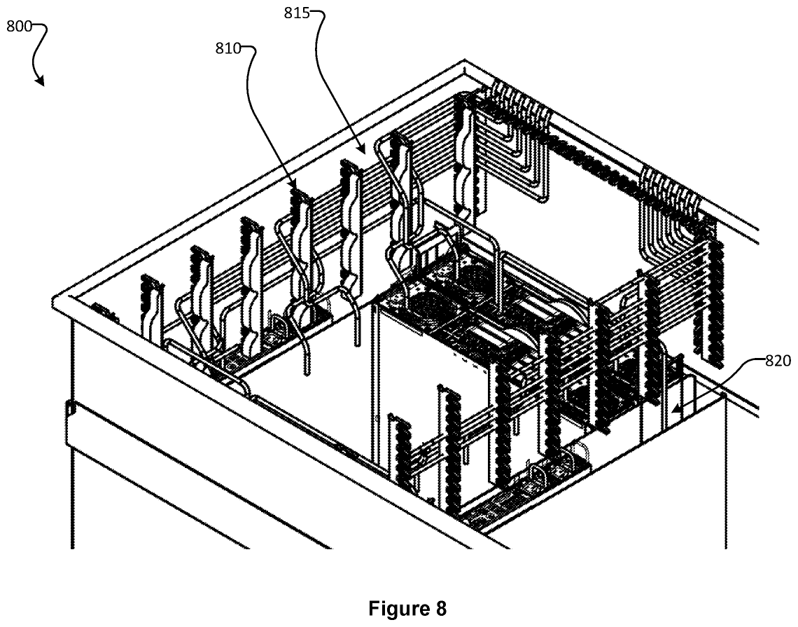

FIG. 8 is a perspective view of cable management system 800, according to some embodiments. Cable management system 800 may comprise brackets 810, cabling 815, and rack cable run 820. Cabling 820 may run from computing device 103 to brackets 810, through brackets 810 to a centrally located control device, such as control device 130. In some embodiments, cabling may be required to be run down into cooling space 312 via rack cable run 820.

Brackets 810 may be 3D printed or injection moulded from plastic and/or formed from machined and/or bent metal such as stainless steel. Brackets 810 may be configured to route cabling 820 from the computing devices along one or more side walls 340, 345. 350 and/or 355 to and/or through and out of the tank 300 via cable management aperture 630.

FIG. 9 has been briefly described above in relation to the use of the plugs 910, 920 to isolate the tank 300. FIG. 9 is subsequently described in more detail. FIG. 9 shows the inside of a tank 300 having inlet conduits 365, outlet conduits 362 and balance conduits 364, according to some embodiments.

The balance conduits 364 may extend from a location near the base of tank 300 to a location at least part way up the tank 300 at which each tank balance conduit 300 may have an open end, (e.g. a threaded end) such that any system coolant above the open end of the balance conduit 364 may be free to enter and exit the balance conduit 364 to facilitate the balancing of system coolant across multiple tanks 300 in system 100.

The outlet conduits 362 may extend from a location near the base of tank 300 to a location at least part way up the tank 300 at which each inlet conduit 362 may have an open end, such that any system coolant above the open end may be free to enter the outlet conduit 362.

In order to fluidically isolate a tank from connecting tanks, a closing member 910 or 920 may be couplable to the open end of each of the balance conduit 364 and the outlet conduit 362. According to some embodiments, closing member 910 and/or 920 may be a plug 910, 920. In some embodiments, closing member 910 and/or 920 may be threaded to screw into the open end of the conduits 362, 364. According to some embodiments, closing member 910 and/or 920 may be a pipe section of sufficient length such that an open end of the pipe section is above the level of liquid coolant in tank 300 when the closing member is in place, such as coupled to the open end of the outlet conduit 362 or the balance conduit 364.

Once located in the open end of the balance conduit 364, closing member 920 may provide a seal that fluidically isolates the balance conduit 364 from the interior volume of tank 300. Tank 300 can then be drained via inlet conduits 365 and/or outlet conduits 362, and removed, replaced or repaired as necessary.

Similarly, once located in the open end of the outlet conduit 362, closing member 910 may provide a seal that fluidically isolates the outlet conduit 362 and therefore branch outlet conduit 152 from the interior volume of tank 300. Tank 300 can then be drained via inlet conduits 365 and/or balance conduits 364, and removed, replaced or repaired as necessary.

In some embodiments, the cooling system for cooling computing devices 100 may implement technology as described in PCT no. PCT/AU2021/051215.

Cooling systems configured as described in some of embodiments may allow for a large quantity of cooling tanks to be connected to a single coolant distribution system, which may have just a single pump and single heat dissipater in some embodiments. When a large quantity of tanks are connected to a single coolant distribution system, it may be important to control the pressure and supply of coolant to each tank to avoid imbalances in the amount of coolant in the components of the system. Such imbalances may cause overflow of tanks if not corrected, in some embodiments. Pipe work systems as described may therefore assist in distributing coolant evenly across multiple tanks of a system having a large quantity of cooling tanks.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

1. A cooling tank for cooling computing devices, the cooling tank comprising:
a plurality of first racking members, configured to engage with at least one side wall of a container configured to contain liquid coolant;
a separation panel disposed within the container to divide the container into a cooling space and a return space;
a plurality of second racking members configured to engage with the plurality of first racking members;
a plurality of third racking members configured to engage with the plurality of second racking members;
wherein the plurality of third racking members are adapted to receive one or more computing devices, such that when the one or more computing devices are received by the plurality of third racking members, the one or more computing devices are mounted within the cooling space in the container; and
wherein when the plurality of first racking members engage with at least one side wall of the container, and each of the plurality of second racking members engages with at least two of the plurality of first racking members, the plurality of first racking members and the plurality of second racking members form a support structure within the container, such that the support structure resists deflection of at least one side wall of the container when the container contains the liquid coolant.

2. The cooling tank of claim 1, wherein the separation panel is disposed proximal to a first side wall of the container, the separation panel defining a plurality of fenestrations and defining the return space between the first side wall and the separation panel.

3. The cooling tank of claim 2, wherein each of the plurality of first racking members comprise one or more first mating structures and each of the plurality of second racking members comprise one or more second mating structures, the one or more second mating structures configured to interact with the one or more first mating structures, and
wherein the one or more first mating structures and the one or more second mating structures are configured to interact through the plurality of fenestrations defined by the separation panel.

4. (canceled)

5. The cooling tank of claim 1, wherein a first edge of the plurality of third racking members is substantially parallel to a bottom panel of the container;
wherein each of the one or more computing devices comprises at least two support brackets, configured to abut against the first edge of the plurality of third racking members; and
wherein when the at least two support brackets of each of the one or more computing devices abuts against the first edge of the plurality of third racking members, the one or more computing devices are caused to hang substantially perpendicular to the bottom panel.

6. The cooling tank of claim 1, wherein each of the plurality of third racking members defines a guide portion, configured to abut against one or more computing devices when one or more computing devices are mounted in a rack.

7. The cooling tank of claim 1, wherein the plurality of second racking members is compatible with one or more of a standard rack unit rack member, a standard rack unit computing device and/or ASIC computing device.

8. The cooling tank of claim 1, wherein one or more of the plurality of first racking members, the plurality of second racking members and/or the plurality of third racking members comprise one or more cable support structures.

9. The cooling tank of claim 1, wherein the plurality of second racking members and/or the plurality of third racking members are further configured to route one or more cables configured to engage with the one or more computing devices.

10. A cooling tank for cooling computing devices comprising:
a container comprising at least four side walls each comprising an external surface, the side walls defining a cooling space, the side walls further defining at least four container edges wherein the container edges are substantially perpendicular to a container base and comprise at least one mounting brackets, each of the at least one mounting brackets comprising at least one first mounting structure, wherein the cooling tank further comprises a racking system configured to support the computing devices within the cooling space; and
a plurality of supporting structures, each supporting structure comprising a set of reinforcing members in contact with the external surface of the at least four side walls, wherein each of the plurality of supporting structures is configured to extend substantially around an outer perimeter of the container defined by the side walls parallel to the container base;
wherein each reinforcing member comprises at least one second mating structure configured to interface with the at least one first mounting structure; and
wherein the reinforcing members substantially resist deflection of the container walls when the container contains liquid coolant.

11. (canceled)

12. The cooling tank of claim 10, wherein the cooling tank comprises a separation panel disposed in an internal space of the container, wherein the separation panel is configured to alter flow characteristics of the liquid coolant.

13. The cooling tank of claim 12, wherein the cooling tank comprises a set of first coolant conduits, a set of second coolant conduits and a set of balance conduits configured to convey liquid coolant in and/or out of the container, and
wherein one of the at least four side walls is a first container wall, and wherein the set of first coolant conduits, the set of second coolant conduits and the set of balance conduits extend between the first container wall and the separation panel.

14. (canceled)

15. The cooling tank of claim 13, wherein the set of first coolant conduits, the set of second coolant conduits and the set of balance conduits is configured to convey liquid coolant into and/or out of the container.

16. The cooling tank of claim 13, wherein the set of balance conduits is further configured to isolate the tank from one or more connected tanks and/or conduits.

17. The cooling tank of claim 10, further comprising at least one set of overflow conduits, and wherein the overflow conduits are in fluidic connection with one or more neighbouring tanks.

18-24. (canceled)

25. The cooling tank of claim 5, wherein the cooling tank further comprises a covering, disposed on an opening of the container, distal from the bottom panel, the covering comprising:
a body portion, the body portion comprising:
a securing portion, for securing the body portion to the container;
one or more cable fenestrations; and
one or more closure control mechanisms;
a lid portion, hingedly connected to the body portion, the lid portion comprising one or more viewing windows; and
wherein the one or more closure control mechanisms are configured to resist movement of the lid portion from an open position to a closed position.

26-27. (canceled)

28. A cooling tank for cooling computing devices, the cooling tank comprising:
a container configured to receive coolant in a cavity of the container, the container comprising a bottom panel and a plurality of side walls extending from the bottom panel, wherein two of the side walls are oppositely disposed;
a separation panel disposed within the container, the separation panel connected to: (i) the oppositely disposed side walls; and (ii) the bottom panel; to divide the container cavity into a cooling space and a return space;
a perforated panel disposed towards the bottom panel of the container and connected to: (i) the oppositely disposed side walls; and (ii) the separation panel; to partition an inlet space from the cooling space;
a racking system configured to support the computing devices within the cooling space;
a coolant inlet conduit configured to release the coolant into the inlet space;
a coolant outlet conduit disposed within the return space and extending out of the container;
wherein perforations defined in the perforated panel are configured to allow passage of the coolant from the inlet space into the cooling space to cool the computing devices therein; and
wherein a top portion of the separation panel is disposed further from the bottom panel compared to an inlet of the coolant outlet conduit.

29. The cooling tank of claim 28, wherein an inlet of the coolant outlet conduit is configured to receive a plug, and
wherein the plug defines a second inlet to the coolant outlet conduit, wherein the second inlet is configured to be disposed further from the bottom panel compared to a top portion of the separation panel.

30. (canceled)

31. The cooling tank of claim 28, wherein the racking system comprises a cover plate configured to receive a top portion of one of the computing devices, wherein the top portion is below the top portion of the separation panel.

32. The cooling tank of claim 28, wherein the racking system is connected to one or both of: (i) the separation panel; and (ii) at least one of the plurality of side walls; to provide structural reinforcement of the container.

33. The cooling tank of claim 28, wherein the coolant inlet conduit is disposed within the return space and extends into the inlet space through apertures in the separation panel.
